(19) United States
(12) Patent Application Publication
(10) Pub. No.: US 2025/0362522 A1
(43) Pub. Date: Nov. 27, 2025

(54) PHOTODETECTION DEVICE

(71) Applicant: SONY GROUP CORPORATION, Tokyo (JP)

(72) Inventors: Hiroki MORITA, Tokyo (JP); Akira AKIBA, Kanagawa (JP); Mai MITA, Kanagawa (JP)

(73) Assignee: SONY GROUP CORPORATION, Tokyo (JP)

(21) Appl. No.: 18/871,933

(22) PCT Filed: May 26, 2023
(86) PCT No.: PCT/JP2023/019614

§ 371 Date: Dec. 5, 2024

(30) Foreign Application Priority Data
Jun. 17, 2022 (JP) 2022-098116

(51) Int. Cl. G02B 27/28; G02B 5/18; G02B 5/30; G02B 19/00; H04N 23/55

(52) U.S. Cl. CPC G02B 27/28; G02B 5/1814; G02B 5/3058; G02B 19/0004; G02B 19/0076; H04N 23/55

(57) ABSTRACT

Provided is a photodetection device including a polarizer having a meta-surface structure, the photodetection device being advantageous for appropriately condensing each polarized light in incident light on a corresponding pixel. The photodetection device includes a polarization control unit that includes a plurality of fine structures arrayed two-dimensionally and selectively emits a plurality of polarized lights in incident light, a photoelectric conversion unit that includes a plurality of pixels receiving the plurality of polarized lights, and a light condensing unit that is positioned between the polarization control unit and the photoelectric conversion unit and condenses the plurality of polarized lights on respectively corresponding pixels.

### TECHNICAL FIELD

The present disclosure relates to a photodetection device.

### BACKGROUND ART

As a method for improving the light receiving sensitivity of a polarization image sensor, a configuration in which an on-chip lens is combined with a polarizer is known. Recently, as another method, a polarization image sensor to which a polarizer including a large number of fine structures called meta-surfaces is applied has also been known.

The polarization image capturing system disclosed in Patent Document 1 includes a wavefront control element including a plurality of fine structures. The wavefront control element has a function of separating two polarized lights from the subject light and forming images of the two polarized lights at different positions on the pixel array.

### CITATION LIST

### Patent Document

Patent Document 1: Japanese Patent Application Laid-Open No. 2020-51868

### SUMMARY OF THE INVENTION

### Problems to be Solved by the Invention

An image sensor (photodetection device) including a polarizer having a meta-surface structure tends to exhibit excellent polarized light receiving sensitivity as compared with an image sensor including an on-chip lens and a polarizer.

However, in a conventional image sensor including a polarizer having a meta-surface structure, each polarized light cannot necessarily be appropriately incident and condensed on the central portion of the corresponding pixel. In particular, as the incident angle of the incident light (imaging light) with respect to the image sensor increases, the polarized light tends to leak out to a pixel adjacent to the corresponding pixel, and as a result, the polarized light receiving sensitivity of the image sensor tends to decrease.

The present disclosure provides a technique advantageous for appropriately condensing each polarized light in incident light on a corresponding pixel in a photodetection device including a polarizer having a meta-surface structure.

### Solutions to Problems

One aspect of the present disclosure relates to a photodetection device including: a polarization control unit that includes a plurality of fine structures arrayed two-dimensionally and selectively emits a plurality of polarized lights in incident light; a photoelectric conversion unit that includes a plurality of pixels receiving the plurality of polarized lights; and a light condensing unit that is positioned between the polarization control unit and the photoelectric conversion unit and condenses the plurality of polarized lights on respectively corresponding pixels.

The light condensing unit may include a diffractive optical element that condenses the plurality of polarized lights on respectively corresponding pixels using diffraction.

The light condensing unit may include a lens that condenses the plurality of polarized lights on respectively corresponding pixels using refraction.

The diffractive optical element may include a plurality of unit diffractive optical elements, and each of the plurality of unit diffractive optical elements may include a central region portion that transmits the plurality of polarized lights and a peripheral region portion that exhibits a refractive index different from a refractive index of the central region portion.

The polarization control unit may include a structure peripheral portion that supports the plurality of fine structures and has a smaller refractive index than the plurality of fine structures, and the central region portion and the structure peripheral portion may include the same material. The central region portion may have a quadrangular, chamfered quadrangular, or oval planar shape.

The plurality of pixels may be arranged along a first array direction and a second array direction perpendicular to the first array direction, the polarization control unit may emit a first polarized light and a second polarized light in the incident light, the first polarized light oscillating in the first array direction and the second polarized light oscillating in the second array direction, and the light condensing unit may condense the first polarized light and the second polarized light on respectively corresponding pixels.

The plurality of pixels may be arranged along a first array direction and a second array direction perpendicular to the first array direction, the polarization control unit may emit a first polarized light and a second polarized light obtained from the incident light, the first polarized light and the second polarized light oscillating in a direction oblique to the first array direction and the second array direction, and the light condensing unit may condense the first polarized light and the second polarized light on respectively corresponding pixels.

The photodetection device may include an additional polarizer that is positioned between the light condensing unit and the photoelectric conversion unit, the additional polarizer may include a plurality of unit additional polarizers associated with each of the plurality of pixels, and each of the plurality of unit additional polarizers may selectively pass a polarized light corresponding to an associated pixel.

The additional polarizer may include a wire grid polarizer.

The additional polarizer may include a photonic crystal polarizer.

The photodetection device may include a band-pass filter, and the photoelectric conversion unit may receive light that has passed through the band-pass filter.

The photodetection device may include an on-chip lens including a plurality of microlenses, and the incident light may be incident on the polarization control unit after passing through the on-chip lens.

Each of the plurality of microlenses may be associated with two or more pixels, and the plurality of polarized lights in the incident light having passed through each of the plurality of microlenses may be incident on two or more pixels associated with each other.

The polarization control unit may include a plurality of unit polarization control units, each of the plurality of unit polarization control units may selectively emit a first polarized light oscillating in a first polarized light oscillation direction and a second polarized light oscillating in a second polarized light oscillation direction in the incident light, a plurality of fine structures included in each of the plurality of unit polarization control units may include a first reference fine structure having a maximum length in the first polarized light oscillation direction, and a plurality of fine structures in which a length in the first polarized light oscillation direction gradually decreases as a distance from the first reference fine structure increases, and a plurality of fine structures included in each of the plurality of unit polarization control units may include a second reference fine structure having a maximum length in the second polarized light oscillation direction, and a plurality of fine structures in which a length in the second polarized light oscillation direction gradually decreases as a distance from the second reference fine structure increases.

Each of the plurality of unit polarization control units may be associated with two pixels among the plurality of pixels, the first polarized light emitted from each of the plurality of unit polarization control units may be condensed on one of the two pixels associated with each other via the light condensing unit, and the second polarized light emitted from each of the plurality of unit polarization control units may be condensed on another one of the two pixels associated with each other via the light condensing unit.

The polarization control unit may include a plurality of unit polarization control units that selectively emits two polarized lights in the incident light, each of the plurality of unit polarization control units may cover a region corresponding to two pixels of the photoelectric conversion unit, and the light condensing unit may include a plurality of unit light condensing units that condenses each of the two polarized lights on an adjacent pixel.

The plurality of unit polarization control units may include: a plurality of first unit polarization control units that selectively emits a first polarized light and a second polarized light in the incident light; and a plurality of second unit polarization control units that selectively emits a third polarized light and a fourth polarized light in the incident light, and the plurality of unit light condensing units may include: a plurality of first unit light condensing units that condenses the first polarized light and the second polarized light on respectively adjacent pixels; and a plurality of second unit light condensing units that condenses the third polarized light and the fourth polarized light on respectively adjacent pixels.

The polarization control unit may include a plurality of sub-unit polarization control units, and each of the plurality of sub-unit polarization controls may include the first unit polarization control unit and the second unit polarization control unit.

### BRIEF DESCRIPTION OF DRAWINGS

FIG. 1 is a schematic diagram illustrating a configuration example of an image sensor.

FIG. 2 is a schematic diagram illustrating a configuration example of a polarization control unit and a photoelectric conversion unit.

FIG. 3 is an enlarged cross-sectional view illustrating a configuration example of a polarization control unit and a pixel (particularly, a pixel positioned in a central portion of a photoelectric conversion unit).

FIG. 4A is a partial cross-sectional view schematically illustrating an example of an image sensor including a light condensing unit, and illustrates a case where incident light perpendicularly enters the image sensor (particularly, polarization control unit).

FIG. 4B is a partial cross-sectional view schematically illustrating an example of an image sensor including a light condensing unit, and illustrates a case where incident light perpendicularly enters the image sensor (particularly, polarization control unit).

FIG. 4C is an enlarged plan view illustrating an example of a light-condensed spot on the corresponding pixel of a first polarized light and a second polarized light in the image sensor illustrated in FIGS. 4A and 4B.

FIG. 5A is a partial cross-sectional view schematically illustrating an example of an image sensor not including a light condensing unit, and illustrates a case where incident light perpendicularly enters the image sensor (particularly, polarization control unit).

FIG. 5B is a partial cross-sectional view schematically illustrating an example of an image sensor not including a light condensing unit, and illustrates a case where incident light perpendicularly enters the image sensor (particularly, polarization control unit).

FIG. 5C is an enlarged plan view illustrating an example of a light-condensed spot on the corresponding pixel of the first polarized light and the second polarized light in the image sensor illustrated in FIGS. 5A and 5B.

FIG. 6A is a partial cross-sectional view of an example of an image sensor including a light condensing unit, and illustrates a case where incident light is obliquely incident on the image sensor (particularly, polarization control unit).

FIG. 6B is an enlarged plan view illustrating an example of a light-condensed spot on the corresponding pixel of the first polarized light and the second polarized light in the image sensor illustrated in FIG. 6A.

FIG. 6C is an enlarged plan view illustrating an example of a light-condensed spot on the corresponding pixel of the first polarized light and the second polarized light in the image sensor illustrated in FIG. 6A.

FIG. 6D is an enlarged plan view illustrating an example of a light-condensed spot on the corresponding pixel of the first polarized light and the second polarized light in the image sensor illustrated in FIG. 6A.

FIG. 7A is a partial cross-sectional view of an example of an image sensor not including a light condensing unit, and illustrates a case where incident light L is obliquely incident on the image sensor (particularly, polarization control unit).

FIG. 7B is an enlarged plan view illustrating an example of a light-condensed spot on the corresponding pixel of the first polarized light and the second polarized light in the image sensor illustrated in FIG. 7A.

FIG. 7C is an enlarged plan view illustrating an example of a light-condensed spot in a case where the photoelectric conversion unit includes pixels (first polarized light pixel and second polarized light pixel) having a size smaller than that of the pixels (first polarized light pixel and second polarized light pixel) illustrated in FIG. 7B.

FIG. 7D is an enlarged plan view illustrating an example of a light-condensed spot in a case where the photoelectric conversion unit includes pixels (first polarized light pixel and second polarized light pixel) having a size smaller than that of the pixels (first polarized light pixel and second polarized light pixel) illustrated in FIG. 7B.

FIG. 8A is a partial cross-sectional view schematically illustrating the image sensor of a first structure example, and illustrates a case where the incident light Lis perpendicularly incident on the image sensor (particularly, polarization control unit).

FIG. 8B is a partial cross-sectional view schematically illustrating the image sensor of a first structure example, and illustrates a case where the incident light Lis perpendicularly incident on the image sensor (particularly, polarization control unit).

FIG. 9 is a cross-sectional view of a polarization control unit (particularly, unit polarization control unit) in the first structure example.

FIG. 10 is a plan view of a diffractive optical element (particularly, unit diffractive optical element) in the first structure example.

FIG. 11A is a partial cross-sectional view schematically illustrating the image sensor of a second structure example, and illustrates a case where the incident light Lis perpendicularly incident on the image sensor (particularly, polarization control unit).

FIG. 11B is a partial cross-sectional view schematically illustrating the image sensor of the second structure example, illustrating a case where the incident light Lis perpendicularly incident on the image sensor (particularly, polarization control unit).

FIG. 12 is a cross-sectional view of a polarization control unit (particularly, unit polarization control unit) in the second structure example.

FIG. 13 is a plan view of a condenser lens (particularly, unit condenser lens) in the second structure example.

FIG. 14A is a partial cross-sectional view schematically illustrating an image sensor of a third structure example, illustrating a case where the incident light L is perpendicularly incident on the image sensor (particularly, polarization control unit).

FIG. 14B is a partial cross-sectional view schematically illustrating the image sensor of the third structure example, and illustrates a case where the incident light L is perpendicularly incident on the image sensor (particularly, polarization control unit).

FIG. 15 is a plan view of a diffractive optical element (particularly, unit diffractive optical element) in a first example of a fourth structure example.

FIG. 16 is a plan view of a diffractive optical element (particularly, unit diffractive optical element) in a second example of the fourth structure example.

FIG. 17 is a heat map illustrating an example of light intensity distributions of the first polarized light and the second polarized light on the photoelectric conversion unit.

FIG. 18 is a cross-sectional view (XY cross section) of a polarization control unit (particularly, unit polarization control unit) in a fifth structure example.

FIG. 19A is a partial cross-sectional view schematically illustrating an image sensor of the fifth structure example, illustrating a case where the incident light Lis perpendicularly incident on the image sensor (particularly, polarization control unit).

FIG. 19B is a partial cross-sectional view schematically illustrating the image sensor of the fifth structure example, illustrating a case where the incident light Lis perpendicularly incident on the image sensor (particularly, polarization control unit).

FIG. 20A is a partial cross-sectional view schematically illustrating an image sensor of a sixth structure example, illustrating a case where the incident light Lis perpendicularly incident on the image sensor (particularly, polarization control unit).

FIG. 20B is a partial cross-sectional view schematically illustrating the image sensor of the sixth structure example, illustrating a case where the incident light Lis perpendicularly incident on the image sensor (particularly, polarization control unit).

FIG. 21 is a plan view illustrating an example of a wire grid polarizer (additional polarizer).

FIG. 22A is a partial cross-sectional view schematically illustrating an image sensor of a seventh structure example, illustrating a case where the incident light Lis perpendicularly incident on the image sensor (particularly, polarization control unit).

FIG. 22B is a partial cross-sectional view schematically illustrating the image sensor of the seventh structure example, and illustrates a case where the incident light Lis perpendicularly incident on the image sensor (particularly, polarization control unit).

FIG. 23 is a plan view illustrating an example of a photonic crystal polarizer (additional polarizer).

FIG. 24A is a partial cross-sectional view schematically illustrating an image sensor of an eighth structure example, illustrating a case where the incident light Lis perpendicularly incident on the image sensor (particularly, polarization control unit).

FIG. 24B is a partial cross-sectional view schematically illustrating the image sensor of the eighth structure example, illustrating a case where the incident light Lis perpendicularly incident on the image sensor (particularly, polarization control unit).

FIG. 25 is a plan view illustrating an example of a band-pass filter (for example, color filter).

FIG. 26A is a partial cross-sectional view schematically illustrating an image sensor of a ninth structure example, illustrating a case where the incident light Lis obliquely incident on the image sensor (particularly, on-chip lens).

FIG. 26B is a partial cross-sectional view schematically illustrating the image sensor of the ninth structure example, illustrating a case where the incident light Lis obliquely incident on the image sensor (particularly, on-chip lens).

FIG. 27 is a plan view illustrating an example of an on-chip lens of the ninth structure example.

FIG. 28A is a partial cross-sectional view schematically illustrating an image sensor of a tenth structure example, illustrating a case where the incident light L is obliquely incident on the image sensor (particularly, on-chip lens).

FIG. 28B is a partial cross-sectional view schematically illustrating an image sensor of the tenth structure example, illustrating a case where the incident light Lis obliquely incident on the image sensor (particularly, on-chip lens).

FIG. 29 is a plan view illustrating an example of an on-chip lens of the tenth structure example.

FIG. 30 is a cross-sectional view (XY cross section) of a polarization control unit (particularly, unit polarization control unit) in an eleventh structure example.

FIG. 31A is a partial cross-sectional view schematically illustrating an image sensor of the eleventh structure example, illustrating a case where the incident light Lis obliquely incident on the image sensor (particularly, polarization control unit).

FIG. 31B is a partial cross-sectional view schematically illustrating an image sensor of the eleventh structure example, illustrating a case where the incident light Lis obliquely incident on the image sensor (particularly, polarization control unit).

FIG. 32 is a cross-sectional view (XY cross section) of a polarization control unit (particularly, sub-unit polarization control unit) in a twelfth structure example.

FIG. 33A is a partial cross-sectional view schematically illustrating an image sensor of the twelfth structure example, illustrating a case where the incident light L is perpendicularly incident on the image sensor (particularly, polarization control unit).

FIG. 33B is a partial cross-sectional view schematically illustrating an image sensor of the twelfth structure example, illustrating a case where the incident light Lis perpendicularly incident on the image sensor (particularly, polarization control unit).

FIG. 33C is a partial cross-sectional view schematically illustrating an image sensor of the twelfth structure example, illustrating a case where the incident light Lis perpendicularly incident on the image sensor (particularly, polarization control unit).

### MODE FOR CARRYING OUT THE INVENTION

Exemplary embodiments of the present disclosure are described below. Hereinafter, a case where the technology of the present disclosure is applied to an image sensor (solid-state imaging device) will be described. However, the application target of the present disclosure technology is not limited, and the present disclosure technology may be applied to other photodetection devices (for example, sensors and the like) applicable to applications other than imaging.

Each element in the drawings is schematically or conceptually illustrated. Therefore, characteristics such as a size and a shape of each element in the drawings may be different from characteristics of an actual corresponding element. Furthermore, a size ratio between elements in the drawings may also be different from a size ratio between corresponding elements in an actual device.

In the following description, the X direction, the Y direction, and the Z direction are directions orthogonal to each other.

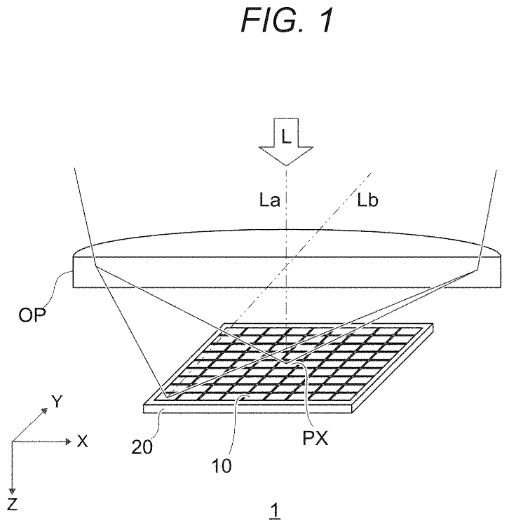

FIG. 1 is a schematic diagram illustrating a configuration example of an image sensor 1. In FIG. 1, a polarization control unit 10 and a photoelectric conversion unit 20 are illustrated in a state of being obliquely viewed, and an optical system OP is illustrated in a state of being viewed from the side.

The image sensor 1 can be typically configured by a charge coupled device (CCD) image sensor and a complementary metal oxide semiconductor (CMOS) image sensor. However, the image sensor 1 can be configured by an arbitrary imaging device.

The image sensor 1 receives light from an external subject, acquires data regarding various types of information including intensity information and color information of the light, and generates an image of the subject. The polarization information of the light from the subject includes useful information that cannot be acquired only from the light intensity and the color (wavelength), and can include, for example, information regarding the shape of the surface of the subject and information regarding the material of the subject. Such a polarization imaging technology using polarization information can be utilized in various fields such as an in-vehicle camera, an Internet of Things (IoT) device, and a medical device.

The image sensor 1 illustrated in FIG. 1 includes an optical system OP, a polarization control unit 10, and a photoelectric conversion unit 20. The optical system OP includes a lens or the like that condenses incident light L from the subject. The incident light L having passed through the optical system OP includes front incident light La traveling in the optical axial direction of the principal ray and inclined incident light Lb traveling in a direction inclined with respect to the optical axis of the principal ray.

The photoelectric conversion unit 20 includes a plurality of pixels PX that receives the incident light L (in the present embodiment, particularly, a plurality of polarized lights extracted from the incident light L). The pixel PX positioned at the central portion (an image height of 0%) of the photoelectric conversion unit 20 receives the front incident light La. The pixel PX positioned away from the central portion of the photoelectric conversion unit 20 (for example, the pixel PX positioned at an end portion (for example, an image height of 100%) of the photoelectric conversion unit 20) receives the inclined incident light Lb. The polarization control unit 10 is disposed on the optical path (polarization path) between the optical system OP and the photoelectric conversion unit 20, and is provided so as to cover the plurality of pixels PX (particularly, the light receiving surface) included in the photoelectric conversion unit 20. In particular, the polarization control unit 10 of the present embodiment has a meta-surface structure including a large number (a plurality) of fine structures (also referred to as “meta-atoms”)

A portion of the polarization control unit 10 covering the pixel PX positioned in the central portion of the photoelectric conversion unit 20 performs polarization control of the front incident light La to condense the front incident light La (particularly, polarized light passing through the polarization control unit 10) on the pixel PX positioned in the central portion of the photoelectric conversion unit 20. A portion of the polarization control unit 10 covering the pixel PX positioned at the end portion of the photoelectric conversion unit 20 performs polarization control of the inclined incident light Lb to condense the inclined incident light Lb (polarized light) on the pixel PX positioned at the end portion of the photoelectric conversion unit 20. As described above, each portion of the polarization control unit 10 has a meta-surface structure capable of performing exit pupil correction so that a specific polarization component included in the incident light L incident at various angles passes therethrough and is condensed on the corresponding pixel PX.

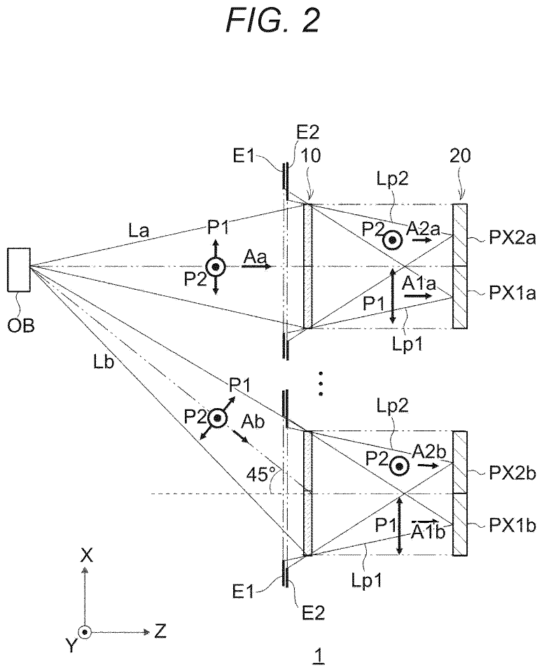

FIG. 2 is a schematic diagram illustrating a configuration example of the polarization control unit 10 and the photoelectric conversion unit 20. In FIG. 2, exit pupils E1 and E2, the polarization control unit 10, and the photoelectric conversion unit 20 are illustrated in a cross-sectional state, and illustration of other elements (for example, the optical system OP (see FIG. 1)) is omitted.

The image sensor 1 further includes the exit pupils E1 and E2 positioned between a subject OB and the polarization control unit 10.

The photoelectric conversion unit 20 includes a plurality of pixels PX1a, PX2a, PX1b, and PX2b two-dimensionally arrayed along the X direction and the Y direction, and incorporates a photodiode that photoelectrically converts incident light and outputs an electric signal. The plurality of pixels included in the photoelectric conversion unit 20 is disposed substantially in the XY plane and constitute a planar light receiving surface. In FIG. 2, the pixel PXla and the pixel PX2a are pixels positioned in the central portion of the photoelectric conversion unit 20 (that is, pixels close to an image height of 0% (center)). On the other hand, the pixel PX1b and the pixel PX2b are pixels positioned at the end portion of the photoelectric conversion unit 20 (for example, pixels close to an image height of 100%). Although four pixels PX1a, PX2a, PX1b, and PX2b are exemplarily illustrated in FIG. 2, the number of pixels included in the photoelectric conversion unit 20 is not limited. The internal configuration of each pixel is not limited, and each pixel may have an arbitrary configuration (for example, a known configuration), and the description of the internal configuration of each pixel is omitted here.

The inclination angle of the incident light is represented by an angle (incident angle) formed by the traveling direction of the incident light with respect to the Z direction. The inclination angle of the front incident light La traveling in the Z direction (that is, a direction perpendicular to the light receiving surface (XY plane) of the photoelectric conversion unit 20; see arrow denoted by the sign “Aa” in FIG. 2) is “0 degrees”. On the other hand, the inclined incident light Lb traveling in a direction non-perpendicular to the XY plane (see the arrow denoted by the sign “Ab” in FIG. 2) has an inclination angle other than 0 degrees (for example, 45 degrees).

The incident light L includes a first polarized light and a second polarized light that oscillate in directions substantially orthogonal to each other. In the front incident light La, a first polarized light oscillation direction P1 that is an oscillation direction of the first polarized light coincides with the X direction, and a second polarized light oscillation direction P2 that is an oscillation direction of the second polarized light coincides with the Y direction. The polarization control unit 10 condenses the first polarized light in the front incident light La to the pixel PXla as indicated by an arrow Ala in FIG. 2, and condenses the second polarized light in the front incident light La to the pixel PX2a as indicated by an arrow A2a.

On the other hand, the inclined incident light Lb illustrated in FIG. 2 is incident on the polarization control unit 10 in a direction inclined by 45 degrees with respect to the Z direction. Therefore, in the inclined incident light Lb, the first polarized light oscillation direction P1 that is the oscillation direction of the first polarized light is inclined by 45 degrees with respect to the X direction, and the second polarized light oscillation direction P2 that is the oscillation direction of the second polarized light coincides with the Y direction. The polarization control unit 10 changes the traveling direction of the inclined incident light Lb (particularly, the first polarized light and the second polarized light) to condense the first polarized light to the pixel PX1b as indicated by an arrow A1b in FIG. 2 and condense the second polarized light to the pixel PX2b as indicated by an arrow A2b.

As described above, the incident direction of the inclined incident light Lb is inclined with respect to the incident direction (Z direction) of the front incident light La, but the traveling direction of the inclined incident light (particularly, the polarization component) is corrected (that is, exit pupil correction) by the polarization control unit 10. As a result, the polarization control unit 10 can condense the first polarized light and the second polarized light in the incident light L on different pixels so that the light intensities of the first polarized light and the second polarized light are separately detected.

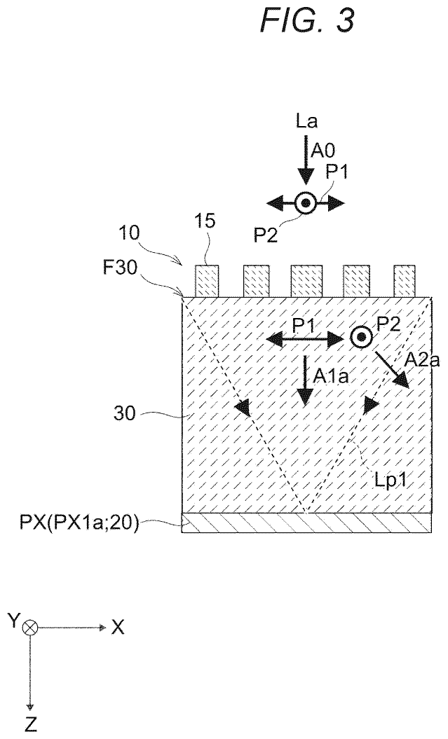

FIG. 3 is an enlarged cross-sectional view illustrating a configuration example of the polarization control unit 10 and the pixel PX (particularly, the pixel PXla positioned at the central portion of the photoelectric conversion unit 20).

In the example illustrated in FIG. 3, a waveguide path 30 is provided between the polarization control unit 10 and each pixel PX (photoelectric conversion unit 20). The waveguide path 30 may have any configuration, and a material that can constitute the waveguide path 30 is not limited. For example, the waveguide path 30 may include a transparent material of any of amorphous silicon, polycrystalline silicon, germanium, titanium oxide, niobium oxide, tantalum oxide, aluminum oxide, hafnium oxide, silicon nitride, silicon oxide, silicon nitride oxide, silicon carbide, silicon carbide oxide, silicon carbide nitride, and zirconium oxide.

A plurality of meta-atoms (fine structures) 15 included in the polarization control unit 10 is two-dimensionally arrayed in the X direction and the Y direction, and is disposed in a plane substantially parallel to the light receiving surface of the pixel PX (photoelectric conversion unit 20). The refractive index of each meta-atom 15 is larger than the refractive index in the region between the meta-atoms 15 (the refractive index of the spatial region between the meta-atoms 15 in the example illustrated in FIG. 3). The meta-atoms 15 can have any configuration, and the material that can constitute each meta-atom 15 is not limited. For example, each meta-atom 15 may include a transparent material of any of amorphous silicon, polycrystalline silicon, germanium, titanium oxide, niobium oxide, tantalum oxide, aluminum oxide, hafnium oxide, silicon nitride, silicon oxide, silicon nitride oxide, silicon carbide, silicon carbide oxide, silicon carbide nitride, and zirconium oxide.

The meta-atom 15 and the waveguide path 30 include different materials from each other. For example, in a case where the waveguide path 30 includes silicon oxide or titanium oxide, the meta-atom 15 may include silicon single crystal or amorphous silicon. Note that, although not illustrated in FIG. 3, another material (structure peripheral portion) may be filled between the meta-atoms 15, and such a structure peripheral portion may include a material different from that of the waveguide path 30 or may include the same material as that of the waveguide path 30.

### [Light Condensing Unit]

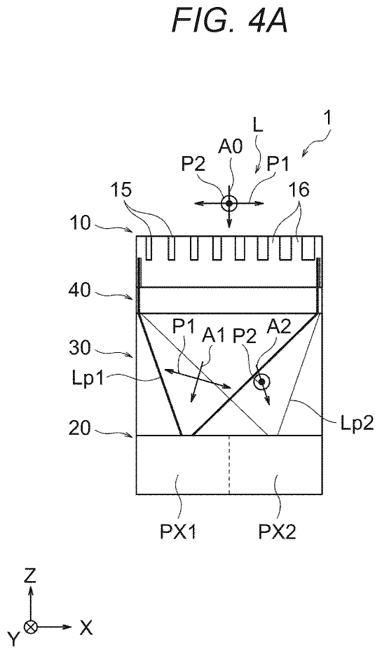

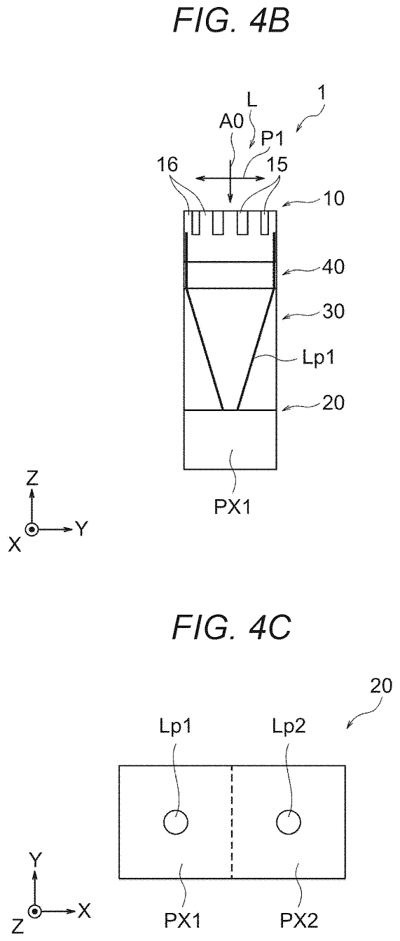

FIGS. 4A and 4B are partial cross-sectional views schematically illustrating examples of the image sensor 1 including a light condensing unit 40, and illustrate a case where the incident light Lis perpendicularly incident on the image sensor 1 (particularly, the polarization control unit 10). FIG. 4A illustrates a cross section (XZ cross section) parallel to the XZ plane, and FIG. 4B illustrates a cross section (YZ cross section) parallel to the YZ plane.

FIG. 4C is an enlarged plan view illustrating an example of light-condensed spots on the corresponding pixels PX1 and PX2 of a first polarized light Lp1 and a second polarized light Lp2 in the image sensor 1 illustrated in FIGS. 4A and 4B. FIG. 4C illustrates an XY plane.

The image sensor 1 of the present embodiment further includes a light condensing unit 40 positioned between the polarization control unit 10 and the photoelectric conversion unit 20. The light condensing unit 40 condenses a plurality of polarized lights (in this example, the first polarized light Lp1 and the second polarized light Lp2) in the incident light L selectively emitted by the polarization control unit 10 on corresponding pixels (in this example, the first polarization pixel PX1 and the second polarization pixel PX2).

A specific configuration of the light condensing unit 40 is not limited.

Typically, the light condensing unit 40 may have a structure that exhibits a light condensing function using “diffraction” and a structure that exhibits a light condensing function using “refraction”. The light condensing unit 40 exhibiting a light condensing function using “diffraction” can be realized by, for example, a diffractive optical element described later. The light condensing unit 40 can realize a structure exhibiting a light condensing function using “refraction” by, for example, a lens described later.

The polarization control unit 10 illustrated in FIGS. 4A and 4B includes a structure peripheral portion 16 filled in a space between the meta-atoms 15 in addition to the plurality of meta-atoms (fine structures) 15. The structure peripheral portion 16 supports the plurality of meta-atoms 15 and has a smaller refractive index than the plurality of meta-atoms 15. The polarization control unit 10 illustrated in FIGS. 4A and 4B selectively transmits the first polarized light Lp1 and the second polarized light Lp2. The first polarized light Lp1 and the second polarized light Lp2 in the incident light L are separated by the polarization control unit 10 and then travel toward the light condensing unit 40.

Both the first polarized light oscillation direction P1, which is the oscillation direction of the first polarized light Lp1, and the second polarized light oscillation direction P2, which is the oscillation direction of the second polarized light Lp2, are perpendicular to an incident direction A0 of the incident light L with respect to the polarization control unit 10.

The oscillation directions of the polarized light spatially separated by the polarization control unit 10 (the first polarized light oscillation direction P1 and the second polarized light oscillation direction P2) can vary depending on the configuration of the meta-atom 15 in the polarization control unit 10.

In the example illustrated in FIGS. 4A and 4B, the plurality of meta-atoms 15 is two-dimensionally disposed so as to be arranged along each of the X direction and the Y direction. The incident direction A0 of the incident light L with respect to the image sensor 1 is the Z direction, and in the incident light L before entering the image sensor 1 (particularly, the polarization control unit 10), the first polarized light oscillation direction P1 is the X direction, and the second polarized light oscillation direction P2 is the Y direction.

As described above, the oscillation directions (the first polarized light oscillation direction P1 and the second polarized light oscillation direction P2) of the first polarized light Lp1 and the second polarized light Lp2 of the present example are perpendicular to each other in the incident light L before entering the image sensor 1.

The first polarized light Lp1 and the second polarized light Lp2 emitted from the polarization control unit 10 are condensed on the corresponding pixels PX1 and PX2 by the light condensing unit 40. That is, the first polarized light Lp1 is condensed on the first polarization pixel PX1, and the second polarized light Lp2 is condensed on the second polarization pixel PX2 adjacent to the first polarization pixel PX1 in the X direction.

As described above, the image sensor 1 of the present embodiment employs the configuration that simultaneously includes the polarization control unit 10 having the meta-surface structure and the light condensing unit 40, and the polarized light condensed by the polarization control unit 10 is further condensed by the light condensing unit 40.

As a result, the image sensor 1 can exhibit very high light condensing performance as a whole, and as illustrated in FIG. 4C, the light-condensed spot of the polarized light (the first polarized light Lp1 and the second polarized light Lp2) on each pixel (the first polarization pixel PX1 and the second polarization pixel PX2) can be reduced. Furthermore, since at least a part of the light condensing function of the image sensor 1 is secured by the light condensing unit 40 provided separately from the polarization control unit 10, the polarization control unit 10 can adopt a configuration focusing on a polarization separation function.

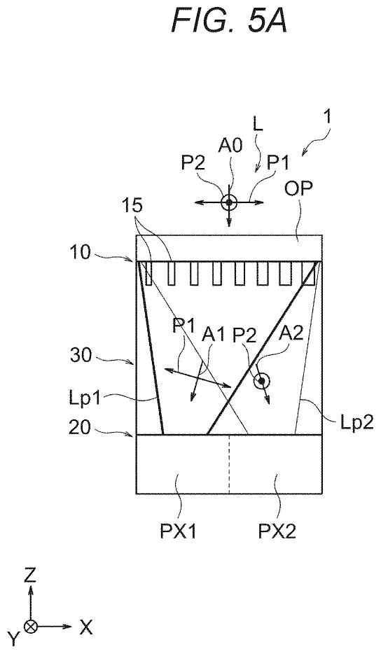

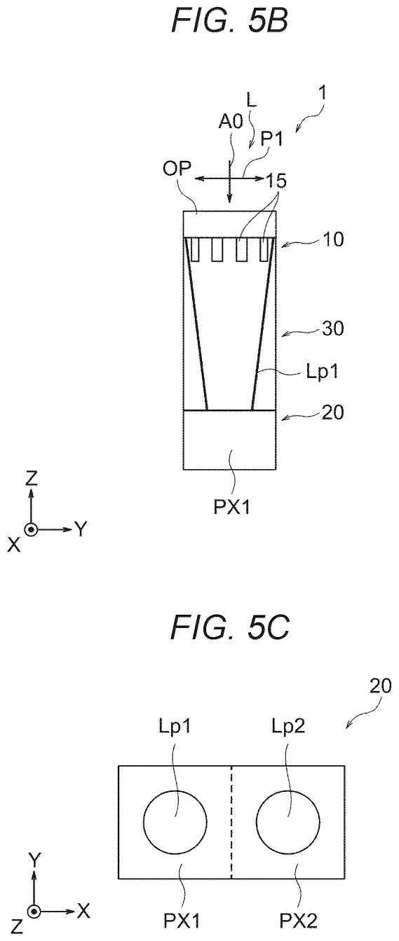

FIGS. 5A and 5B are partial cross-sectional views schematically illustrating examples of the image sensor 1 not including the light condensing unit 40, and illustrate a case where the incident light Lis perpendicularly incident on the image sensor 1 (particularly, the polarization control unit 10). FIG. 5C is an enlarged plan view illustrating an example of light-condensed spots on the corresponding pixels PX1 and PX2 of the first polarized light Lp1 and the second polarized light Lp2 in the image sensor 1 illustrated in FIGS. 5A and 5B.

The image sensor 1 (see FIGS. 5A and 5B) not including the light condensing unit 40 is inferior in light condensing performance to the above-described image sensor 1 (see FIGS. 4A and 4B) including the light condensing unit 40.

Therefore, the light-condensed spot diameter (see FIG. 5C) on each pixel of the image sensor 1 not including the light condensing unit 40 is larger than the light-condensed spot diameter (see FIG. 4C) on each pixel of the image sensor 1 including the light condensing unit 40.

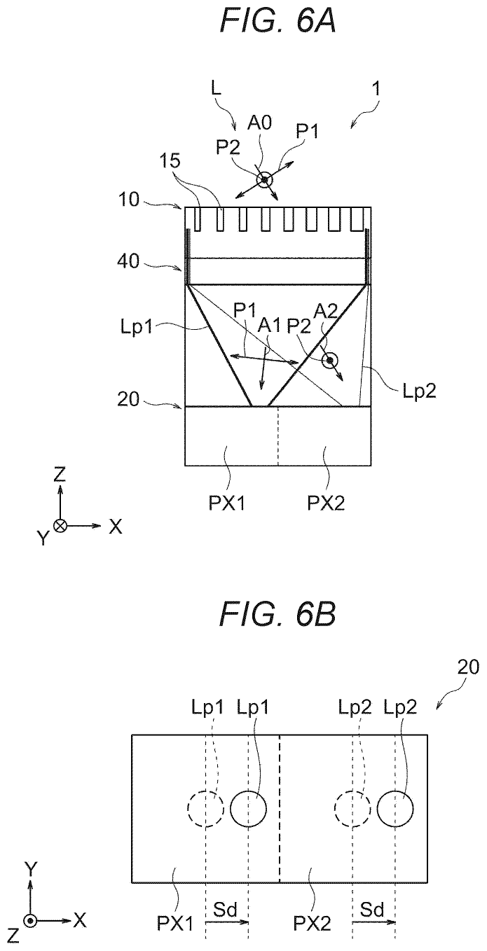

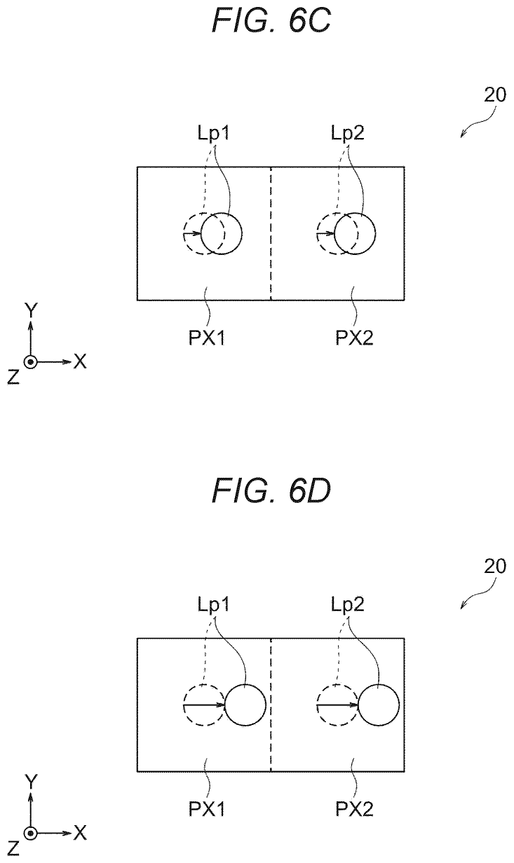

FIG. 6A is a partial cross-sectional view of the image sensor 1 including the light condensing unit 40, and illustrates a case where the incident light Lis obliquely incident on the image sensor 1 (particularly, the polarization control unit 10). FIG. 6B is an enlarged plan view illustrating an example of light-condensed spots on the corresponding pixels PX1 and PX2 of the first polarized light Lp1 and the second polarized light Lp2 in the image sensor 1 illustrated in FIG. 6A.

FIGS. 6C and 6D are enlarged plan views illustrating examples of light-condensed spots on the corresponding pixels PX1 and PX2 of the first polarized light Lp1 and the second polarized light Lp2 in the image sensor 1 illustrated in FIG. 6A. In particular, FIGS. 6C and 6D illustrate examples of light-condensed spots in a case where the photoelectric conversion unit 20 includes pixels (the first polarization pixel PX1 and the second polarization pixel PX2) smaller in size than the pixels (the first polarization pixel PX1 and the second polarization pixel PX2) illustrated in FIG. 6B. FIG. 6C illustrates a case where the incident angle of the incident light Lis relatively small, and FIG. 6D illustrates a case where the incident angle of the incident light L is relatively large.

In a case where the incident light Lis perpendicularly incident on the image sensor 1 (incident angle=0 degrees), the image sensor 1 in which each polarized light is basically condensed at the center of the corresponding pixel is assumed (see FIGS. 4C and 6B to 6D (particularly, dotted line portions) described above). In the image sensor 1, in a case where the incident light Lis obliquely incident on the image sensor 1 (incident angle/0 degrees; see FIG. 6A), the polarized lights Lp1 and Lp2 each are condensed at positions shifted from the centers of the corresponding pixels PX1 and PX2 (see FIG. 6B).

A shift amount Sd of the light-condensed spot on each of the pixels PX1 and PX2 changes according to the incident angle of the incident light L. That is, as the inclination of the incident direction A0 of the incident light L increases (that is, as the absolute value of the incident angle increases), the shift amount Sd of the light-condensed spot increases, and each of the polarized lights Lp1 and Lp2 forms a light-condensed spot at a position away from the center of the corresponding pixels PX1 and PX2.

According to the image sensor 1 (see FIG. 6A) including the light condensing unit 40, the light-condensed spot diameter is small as described above. Therefore, even if the inclination of the incident direction A0 of the incident light Lis large and the position of the light-condensed spot on the photoelectric conversion unit 20 is greatly shifted, the light-condensed spot tends to stay within the range of the corresponding pixel (FIG. 6B). As a result, leakage of the polarized lights Lp1 and Lp2 to the pixels adjacent to the corresponding pixels PX1 and PX2 can be effectively suppressed.

Such suppression of leakage of each polarized light to the adjacent pixel is effective even in a case where the size of each pixel is small. That is, according to the image sensor 1 including the light condensing unit 40, leakage of the polarized lights Lp1 and Lp2 to the adjacent pixels PX1 and PX2 can be effectively suppressed not only in a case where the shift amount of the light-condensed spot is small (see FIG. 6C) but also in a case where the shift amount is large (see FIG. 6D).

As described above, the image sensor 1 including the light condensing unit 40 can effectively suppress light leakage (polarization leakage) to the adjacent pixels even if the miniaturization of the pixels progresses, and can provide highly accurate light reception (light detection).

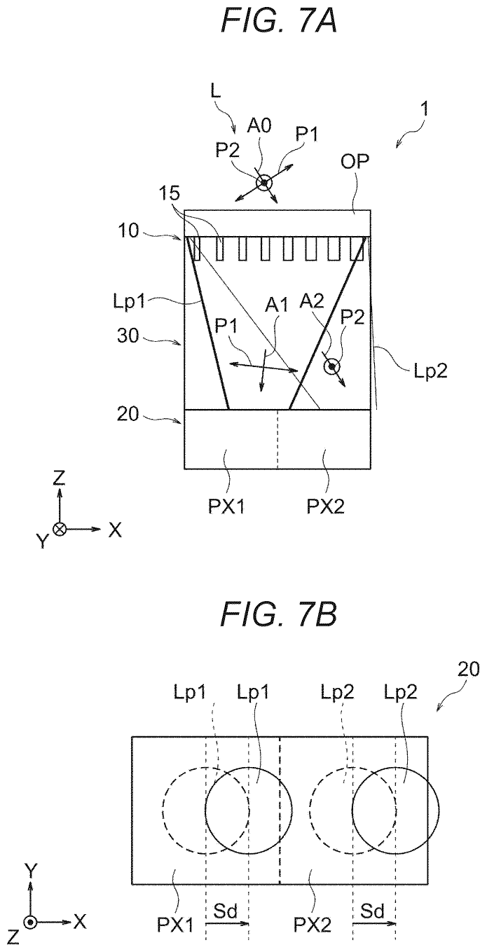

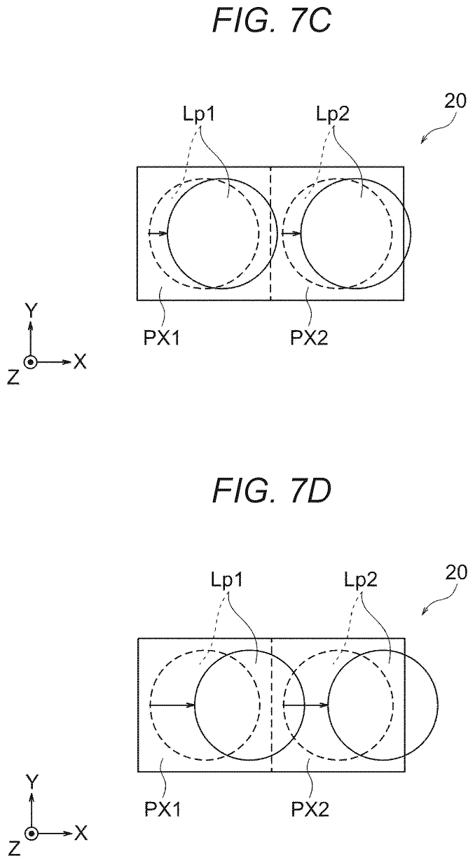

FIG. 7A is a partial cross-sectional view of the image sensor 1 not including the light condensing unit 40, and illustrates a case where the incident light Lis obliquely incident on the image sensor 1 (particularly, the polarization control unit 10). FIG. 7B is an enlarged plan view illustrating an example of light-condensed spots on the corresponding pixels PX1 and PX2 of the first polarized light Lp1 and the second polarized light Lp2 in the image sensor 1 illustrated in FIG. 7A.

FIGS. 7C and 7D are enlarged plan views illustrating examples of the light-condensed spots in a case where the photoelectric conversion unit 20 includes pixels (the first polarization pixel PX1 and the second polarization pixel PX2) smaller in size than the pixels (the first polarization pixel PX1 and the second polarization pixel PX2) illustrated in FIG. 7B. FIG. 7C illustrates a case where the incident angle of the incident light L is relatively small, and FIG. 7D illustrates a case where the incident angle of the incident light L is relatively large.

In the image sensor 1 not including the light condensing unit 40, as described above, the light-condensed spot diameter on each pixel is large.

Therefore, even if the inclination of the incidence of the incident light L is not so large and the shift amount Sd of the position of the light-condensed spot on each pixel is not so large, the light-condensed spot easily protrudes to the pixel adjacent to the corresponding pixel (FIG. 7B). As a result, color mixing between adjacent pixels is likely to occur.

Such leakage of each polarized light to the adjacent pixel tends to be more noticeable as the size of each pixel decreases (that is, as the ratio of the light-condensed spot area to the light receiving area of each pixel increases). That is, in a case where the image sensor 1 does not include the light condensing unit 40, leakage of each polarized light to the adjacent pixel occurs even if the shift amount of the light-condensed spot is small (see FIG. 7C), and when the shift amount is large, the amount and range of leakage of each polarized light to the adjacent pixel tend to be significantly large (see FIG. 7D).

Next, a specific structure example of the image sensor 1 including the light condensing unit 40 will be described.

### First Structure Example

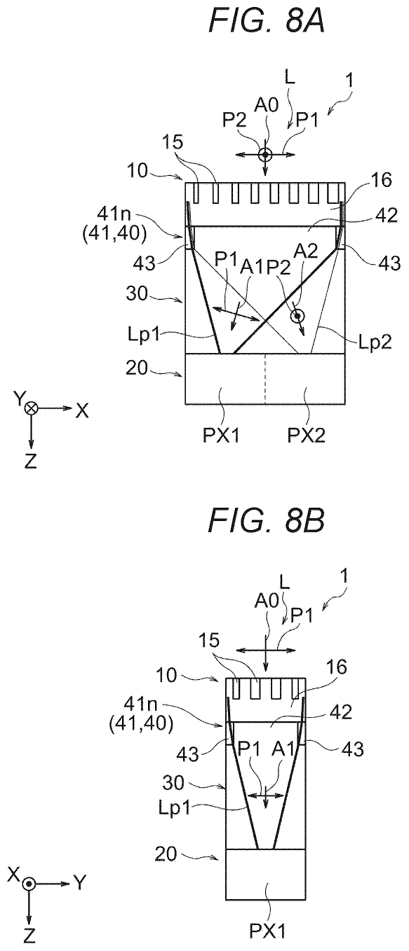

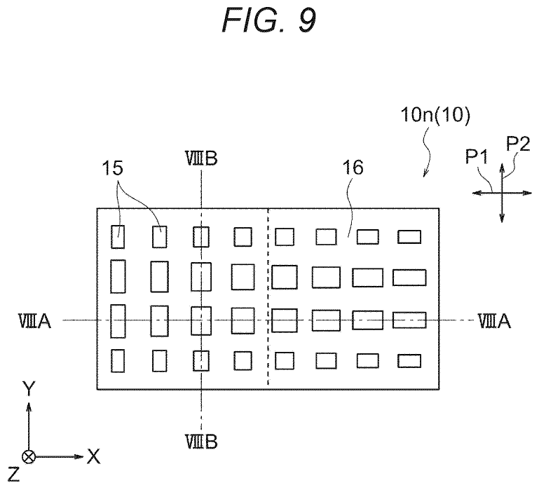

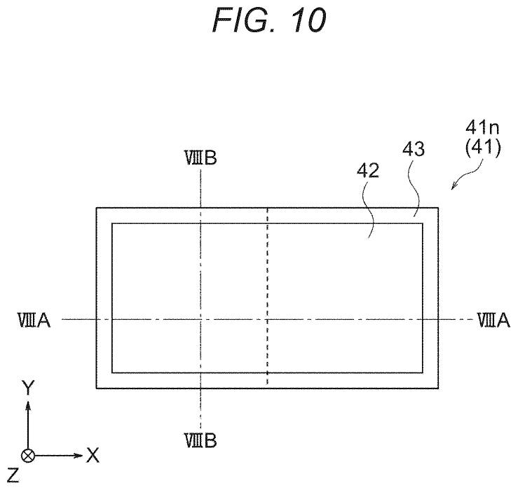

FIGS. 8A and 8B are partial cross-sectional views schematically illustrating the image sensor 1 of the first structure example, and illustrate a case where the incident light Lis perpendicularly incident on the image sensor 1 (particularly, the polarization control unit 10). FIG. 9 is a cross-sectional view of the polarization control unit 10 (particularly, the unit polarization control unit 10n) in the first structure example. FIG. 10 is a plan view of a diffractive optical element 41 (particularly, a unit diffractive optical element 41n) in the first structure example.

FIG. 8A illustrates a cross section (XZ cross section) taken along the cross-sectional line VIIIA-VIIIA in FIGS. 9 and 10. FIG. 8B illustrates a cross section (YZ plane) along the cross-sectional line VIIIB-VIIIB in FIGS. 9 and 10. FIG. 9 illustrates a cross section (XY cross section) parallel to the XY plane. FIG. 10 illustrates a planar structure parallel to the XY plane. Note that the XY cross-sectional structure of the diffractive optical element 41 (unit diffractive optical element 41n) substantially coincides with the planar structure illustrated in FIG. 10.

The light condensing unit 40 of the present structure example includes a diffractive optical element 41. The diffractive optical element 41 condenses the plurality of polarized lights (the first polarized light Lp1 and the second polarized light Lp2) on the corresponding pixels (the first polarization pixel PX1 and the second polarization pixel PX2) using diffraction.

The diffractive optical element 41 of the present example includes a plurality of unit diffractive optical elements 4 In (see FIG. 10) two-dimensionally arranged in each of the X direction and the Y direction. In other words, the diffractive optical element 41 is divided into a plurality of unit diffractive optical elements 41n arrayed two-dimensionally.

Each unit diffractive optical element 41n is provided in a range (that is, a region covering two pixels) corresponding to two pixels (that is, one first polarization pixel PX1 and one second polarization pixel PX2) of the photoelectric conversion unit 20. The unit diffractive optical element 41n illustrated in FIG. 10 is provided so as to cover two pixels adjacent in the X direction, and a half region on one side of the unit diffractive optical element 41n covers the first polarization pixel PX1 and a half region on the other side covers the second polarization pixel PX2.

Each unit diffractive optical element 41n includes a central region portion 42 and a peripheral region portion 43 surrounding the central region portion 42. In the example illustrated in FIG. 10, the central region portion 42 has a rectangular planar shape, and the peripheral region portion 43 has a planar shape having rectangular inner contour and outer contour.

The central region portion 42 transmits the plurality of polarized lights (the first polarized light Lp1 and the second polarized light Lp2) from the polarization control unit 10.

The peripheral region portion 43 has a refractive index different from that of the central region portion 42. The refractive index of the central region portion 42 may be higher (refractive index of the central region portion 42>refractive index of the peripheral region portion 43) or lower (refractive index of the central region portion 42<refractive index of the peripheral region portion 43) than the refractive index of the peripheral region portion 43. The light condensing performance (light condensing effect) of the unit diffractive optical element 41n tends to increase as the refractive index difference between the central region portion 42 and the peripheral region portion 43 increases.

The central region portion 42 and the peripheral region portion 43 can include an arbitrary material (composition).

For example, the materials (composition) of the central region portion 42 and the peripheral region portion 43 can be appropriately selected from Si, α-Si, SiO₂, SiN, Si₃N₄, SiC, TiO₂, GaN, GaAs, InP, and air. As an example, the unit diffractive optical element 41n may be configured by combining the central region portion 42 including SiO₂ and the peripheral region portion 43 including air.

As described above, the diffractive optical element 41 (light condensing unit 40) of the present example exerts a light condensing function using diffraction (particularly, aperture diffraction) based on a combination of the central region portion 42 and the peripheral region portion 43. Since diffraction has no polarization dependency, each of the plurality of polarized lights (the first polarized light Lp1 and the second polarized light Lp2) emitted from the polarization control unit 10 is condensed on the corresponding pixel (the first polarization pixel PX1 and the second polarization pixel PX2) by the diffractive optical element 41.

The polarization control unit 10 in the present structure example includes the above-described large number of meta-atoms 15 and the structure peripheral portion 16 surrounding each meta-atom 15.

In the examples illustrated in FIGS. 8A and 8B, the space between the meta-atoms 15 is filled with the structure peripheral portion 16 and extends in the X direction and the Y direction, and extends in the Z direction between the plurality of meta-atoms 15 and the diffractive optical element 41. Therefore, the plurality of meta-atoms 15 is supported by the structure peripheral portion 16 from each of the X direction, the Y direction, and the Z direction.

The waveguide path 30 illustrated in FIGS. 8A and 8B includes the structure peripheral portion 16 positioned between the plurality of meta-atoms 15 and the diffractive optical element 41, the diffractive optical element 41, and a member positioned between the diffractive optical element 41 and the photoelectric conversion unit 20.

The central region portion 42 of the diffractive optical element 41 has the same composition (material) as a member positioned between the diffractive optical element 41 and the photoelectric conversion unit 20, and is configured integrally with the member. However, the central region portion 42 of the present structure example has a composition (material) different from that of the adjacent structure peripheral portion 16.

The polarization control unit 10 includes a plurality of unit polarization control units 10n (see FIG. 9) arranged two-dimensionally in each of the X direction and the Y direction. In other words, the polarization control unit 10 is divided into the plurality of unit polarization control units 10n arrayed two-dimensionally.

Each unit polarization control unit 10n is provided in a range (that is, a region covering two pixels) corresponding to two pixels (that is, one first polarization pixel PX1 and one second polarization pixel PX2) of the photoelectric conversion unit 20. The unit polarization control unit 10n illustrated in FIG. 9 is provided so as to cover two pixels adjacent in the X direction, and a half region on one side of the unit polarization control unit 10n covers the first polarization pixel PX1 and a half region on the other side covers the second polarization pixel PX2.

The plurality of meta-atoms 15 included in each unit polarization control unit 10n is linearly arrayed along each of the oscillation direction (first polarized light oscillation direction P1: X direction) of the first polarized light Lp1 and the oscillation direction (second polarized light oscillation direction P2: Y direction) of the second polarized light Lp2.

Furthermore, the plurality of meta-atoms 15 of each unit polarization control unit 10n includes a plurality of meta-atoms 15 having different sizes in each of the oscillation direction (first polarized light oscillation direction P1: X direction) of the first polarized light Lp1 and the oscillation direction (second polarized light oscillation direction P2: Y direction) of the second polarized light Lp2 in the incident light L.

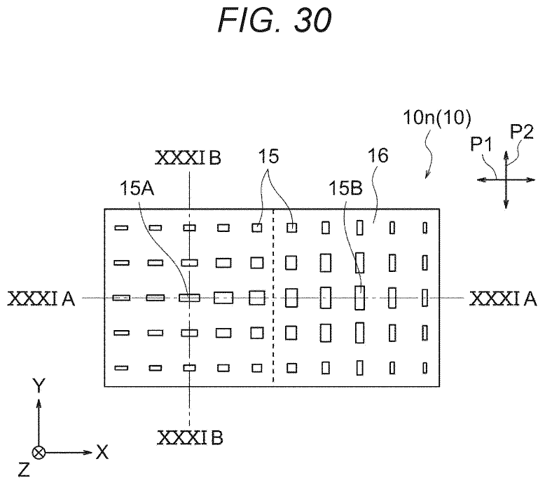

The specific array and size of the plurality of meta-atoms 15 of each unit polarization control unit 10n are not limited. As an example, the plurality of meta-atoms 15 of each unit polarization control unit 10n can have an array and a size as illustrated in FIG. 30 (eleventh structure example) to be described later.

Since the plurality of meta-atoms 15 has the above-described structure and size, each unit polarization control unit 10n selectively emits the first polarized light Lp1 and the second polarized light Lp2 included in the incident light L toward the diffractive optical element 41 and the photoelectric conversion unit 20.

In the example illustrated in FIG. 9, each meta-atom 15 has a rectangular cross-sectional shape and a planar shape, but the shape of each meta-atom 15 is not limited. For example, the cross-sectional shape and planar shape of each meta-atom 15 may be any polygonal shape, elliptical shape, hollow shape, or other shapes.

The refractive index of each meta-atom 15 is larger than the refractive index of the structure peripheral portion 16, but each meta-atom 15 and the structure peripheral portion 16 can include an arbitrary material (composition). For example, the material (composition) of each meta-atom 15 can be appropriately selected from Si, α-Si, SiO₂, SiN, Si₃N₄, SiC, TiO₂, GaN, GaAs, and InP in addition to the above-described material examples.

The plurality of pixels included in the photoelectric conversion unit 20 is arranged along a first array direction (X direction) and a second array direction (Y direction) perpendicular to the first array direction. Furthermore, the plurality of pixels included in the photoelectric conversion unit 20 includes a plurality of unit pixel groups (see FIG. 8A) two-dimensionally arranged in each of the X direction and the Y direction. In other words, the plurality of pixels of the photoelectric conversion unit 20 is divided into a plurality of unit pixel groups arrayed two-dimensionally.

Each unit pixel group of this example includes two pixels. The two pixels include one first polarization pixel PX1 intended to receive the first polarized light Lp1 and one second polarization pixel PX2 intended to receive the second polarized light Lp2.

A specific unit polarization control unit 10n and a specific unit diffractive optical element 41n are associated with each unit pixel group. Basically, the first polarized light Lp1 and the second polarized light Lp2 having passed through the associated unit polarization control unit 10n and unit diffractive optical element 41n are incident on each unit pixel group.

As described above, in the image sensor 1 of the first structure example illustrated in FIGS. 8A to 10, the diffraction type light condensing unit 40 (diffractive optical element 41) is provided between the polarization control unit 10 having the meta-surface structure and the photoelectric conversion unit 20.

According to the image sensor 1, the plurality of polarized lights (specifically, the first polarized light Lp1 and the second polarized light Lp2) separated from the incident light L can be highly condensed on the corresponding pixels (the first polarization pixel PX1 and the second polarization pixel PX2). Therefore, according to the image sensor 1 of the present structure example, it is possible to provide a polarization image sensor having a high angle of view and high sensitivity.

### Second Structure Example

In the present structure example, the same or corresponding elements as those in the above-described first structure example are denoted by the same reference numerals, and a detailed description thereof will be omitted.

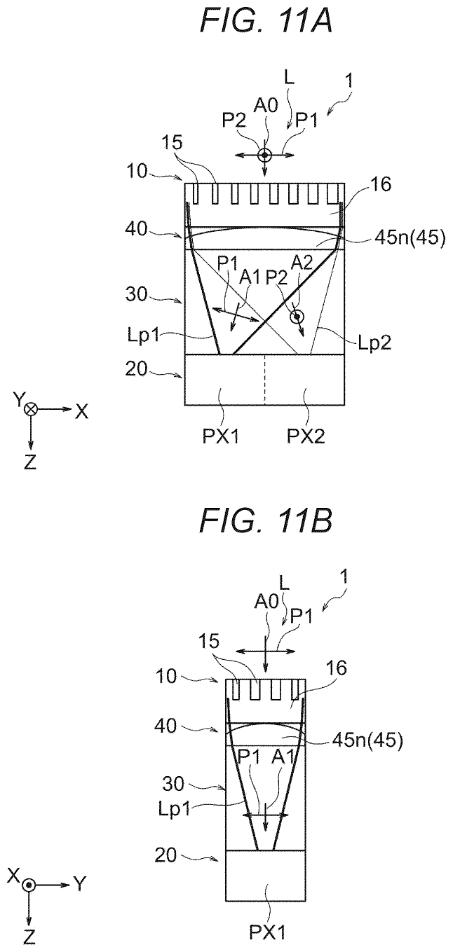

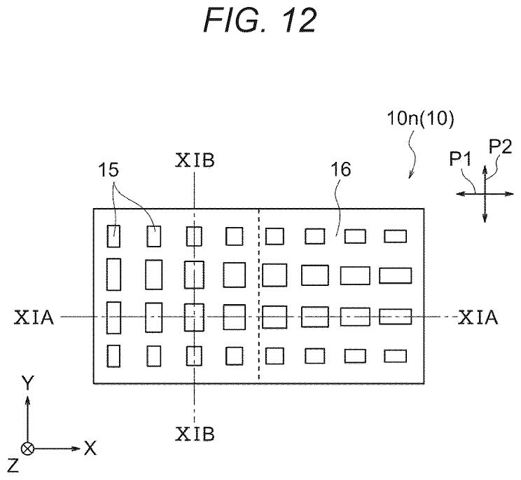

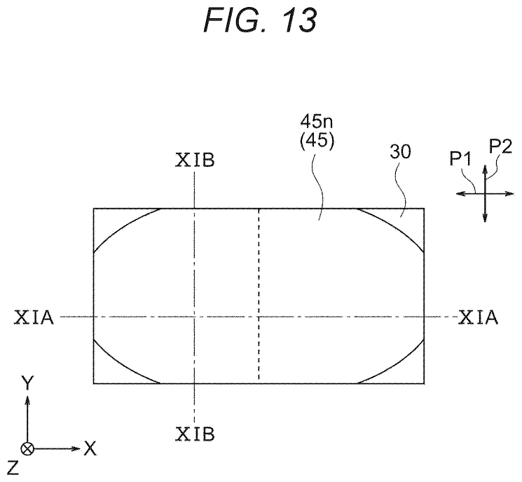

FIGS. 11A and 11B are partial cross-sectional views schematically illustrating an image sensor 1 of the second structure example, and illustrate a case where the incident light Lis perpendicularly incident on the image sensor 1 (particularly, the polarization control unit 10). FIG. 12 is a cross-sectional view of the polarization control unit 10 (particularly, the unit polarization control unit 10n) in the second structure example. FIG. 13 is a plan view of a condenser lens 45 (particularly, a unit condenser lens 45n) in the second structure example.

FIG. 11A illustrates a cross section (XZ cross section) along the cross-sectional line XIA-XIA in FIGS. 12 and 13. FIG. 11B illustrates a cross section (YZ cross section) along the cross-sectional line XIB-XIB in FIGS. 12 and 13. FIG. 12 illustrates a cross section parallel to the XY plane. FIG. 13 illustrates a planar structure parallel to the XY plane.

The light condensing unit 40 of the present structure example includes a condenser lens (inner lens) 45. The condenser lens 45 condenses the plurality of polarized lights (the first polarized light Lp1 and the second polarized light Lp2) on the corresponding pixels (the first polarization pixel PX1 and the second polarization pixel PX2) using refraction.

The condenser lens 45 of the present example includes a plurality of unit condenser lenses 45n (see FIG. 13) two-dimensionally arranged in each of the X direction and the Y direction. In other words, the condenser lens 45 is configured by a set of a plurality of unit condenser lenses 45n arrayed two-dimensionally.

Each unit condenser lens 45n is provided in a range (that is, a region covering two pixels) corresponding to two pixels (that is, one first polarization pixel PX1 and one second polarization pixel PX2) of the photoelectric conversion unit 20. In other words, one unit condenser lens (one inner lens) 45n is provided for two pixel regions. The unit condenser lens 45n illustrated in FIG. 13 is provided so as to cover two pixels adjacent in the X direction, and a half region on one side of the unit condenser lens 45n covers the first polarization pixel PX1 and a half region on the other side covers the second polarization pixel PX2.

The unit condenser lens 45n can include any material (composition). For example, the material (composition) of the unit condenser lens 45n can be appropriately selected from dielectrics Si, α-Si, SiO₂, SiN, Si₃N₄, SiC, TiO₂, GaN, GaAs, and InP.

As described above, the light condensing unit 40 of the present example exhibits a light condensing function using refraction of the condenser lens 45. Since refraction has no polarization dependency, each of the plurality of polarized lights (the first polarized light Lp1 and the second polarized light Lp2) emitted from the polarization control unit 10 is condensed on the corresponding pixel (the first polarization pixel PX1 and the second polarization pixel PX2) by the condenser lens 45.

Other configurations of the image sensor 1 of the present structure example are similar to those of the image sensor 1 of the above-described first structure example (FIGS. 8A to 10).

As described above, in the image sensor 1 of the second structure example illustrated in FIGS. 11A to 13, the refraction type light condensing unit 40 (condenser lens 45) is provided between the polarization control unit 10 having the meta-surface structure and the photoelectric conversion unit 20.

According to the image sensor 1, the plurality of polarized lights Lp1 and Lp2 separated from the incident light L can be highly condensed on the corresponding pixels PX1 and PX2, similarly to the above-described first structure example including the diffraction type light condensing unit 40.

### Third Structure Example

In the present structure example, the same or corresponding elements as those in the above-described first structure example are denoted by the same reference numerals, and a detailed description thereof will be omitted.

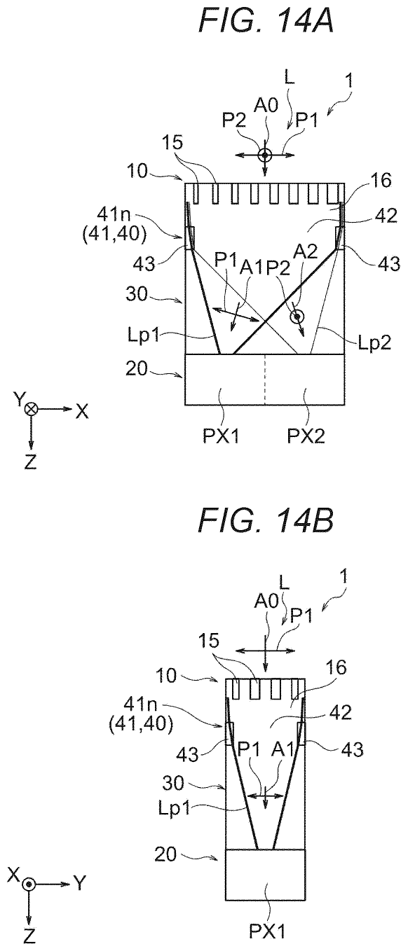

FIGS. 14A and 14B are partial cross-sectional views schematically illustrating an image sensor 1 of the third structure example, and illustrate a case where the incident light Lis perpendicularly incident on the image sensor 1 (particularly, the polarization control unit 10).

In the present structure example, the structure peripheral portion 16 and the central region portion 42 of the diffractive optical element 41 (light condensing unit 40) include the same material (composition) and are integrally provided.

Therefore, the waveguide path 30 (the central region portion 42 (excluding the peripheral region portion 43) with respect to the diffractive optical element 41 (the light condensing unit 40)) positioned between the plurality of meta-atoms 15 and the photoelectric conversion unit 20 (the plurality of pixels) can be integrally configured by the same material.

Other configurations of the image sensor 1 of the present structure example are similar to those of the image sensor 1 of the above-described first structure example (FIGS. 8A to 10). As described above, in the image sensor 1 of the third structure example illustrated in FIGS. 14A and 14B, the structure peripheral portion 16 and the central region portion 42 include the same material between the polarization control unit 10 having the meta-surface structure and the photoelectric conversion unit 20.

According to the image sensor 1, there is no boundary surface between the structure peripheral portion 16 and the central region portion 42, and it is possible to prevent the refractive index from changing in the middle of the waveguide path 30. As a result, reflection of polarized light (the first polarized light Lp1 and the second polarized light Lp2) is prevented from occurring between the structure peripheral portion 16 and the central region portion 42, and reflection loss of polarized light can be reduced.

### Fourth Structure Example

In the present structure example, the same or corresponding elements as those in the above-described first structure example are denoted by the same reference numerals, and a detailed description thereof will be omitted.

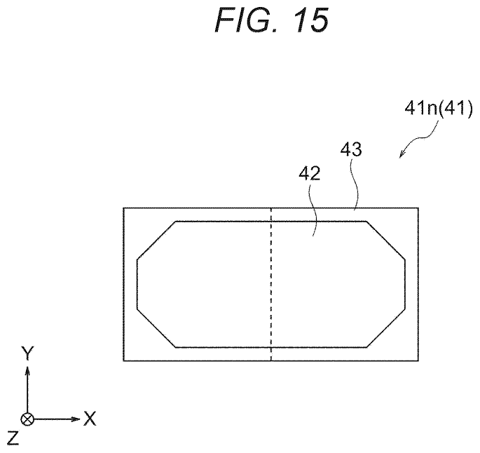

FIG. 15 is a plan view of the diffractive optical element 41 (particularly, the unit diffractive optical element 41n) in the first example of the fourth structure example.

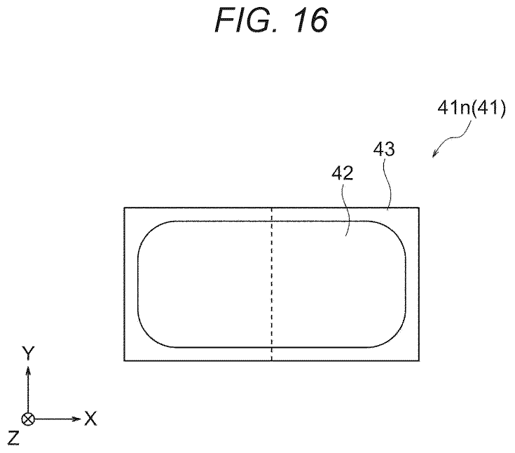

FIG. 16 is a plan view of the diffractive optical element 41 (particularly, the unit diffractive optical element 41n) in the second example of the fourth structure example.

The planar shape of the central region portion 42 of the diffractive optical element 41 (the light condensing unit 40) is not limited to the above-described rectangle (quadrangular (see FIG. 10)), and may have a planar shape of a chamfered quadrangular (see FIG. 15), an oval shape (see FIG. 16), or any other shape (for example, polygon).

The “chamfered quadrangle” referred to herein is a shape in which four corners of the quadrangle are cut off. The “oval shape” includes, for example, an egg shape, an ellipse, and an elliptical shape.

Other configurations of the image sensor 1 of the present structure example are similar to those of the image sensor 1 of the above-described first structure example (FIGS. 8A to 10).

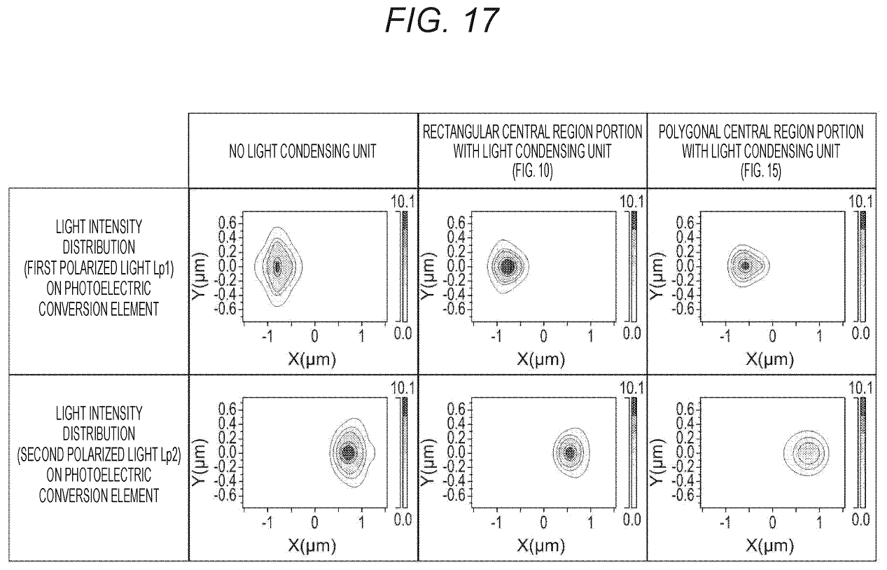

FIG. 17 is a heat map illustrating an example of the light intensity distribution of the first polarized light Lp1 and the second polarized light Lp2 on the photoelectric conversion unit 20.

In FIG. 17, “no light condensing unit” indicates a measurement result (simulation result) using the image sensor 1 (see FIGS. 5A and 5B) in which the light condensing unit 40 is not provided. In FIG. 17, a “rectangular central region portion with light condensing unit” indicates a measurement result (simulation result) using the image sensor 1 (see FIGS. 8A to 10) including the diffractive optical element 41 as the light condensing unit 40 and having a rectangular planar shape in the central region portion 42. In FIG. 17, a “polygonal central region portion with light condensing unit” indicates a measurement result (simulation result) using the image sensor 1 (see FIG. 15) including the diffractive optical element 41 as the light condensing unit 40, particularly, the central region portion 42 having a chamfered quadrangular planar shape.

Each heat map of FIG. 17 illustrates a light reception result in a unit pixel group including two pixels (the first polarization pixel PX1 and the second polarization pixel PX2) adjacent in the X direction. The X-axis of each heat map in FIG. 17 indicates the X-direction position of the light reception on the pixel of the unit pixel group, and the Y-axis indicates the Y-direction position of the light reception on the pixel of the unit pixel group. Therefore, in each heat map, a relatively left region indicates the light reception result of the first polarization pixel PX1 intended to receive the first polarized light Lp1, and a relatively right region indicates the light reception result of the second polarization pixel PX2 intended to receive the second polarized light Lp2.

The grayscale display in each heat map of FIG. 17 indicates the intensity of the polarized light (the first polarized light Lp1 and the second polarized light Lp2) received by the unit pixel group. A darker color indicates a higher intensity of the polarized light received by the unit pixel group.

Therefore, in each heat map, it is indicated that the polarized light with relatively strong intensity is received in a region where the grayscale display other than white is performed (that is, a non-blank region (non-white region)).

On the other hand, in each heat map, a region represented by white (that is, a blank region (white region)) is a region where polarized light with relatively weak intensity is received (including a region where polarized light is not received at all). Note that, in the blank region of each heat map, in order to avoid complexity of display, grayscale display of a region where polarized light with relatively weak intensity is received is omitted, and is uniformly indicated in white.

In FIG. 17, the light reception result of the first polarized light Lp1 is illustrated in a field indicated by “light intensity distribution (first polarized light Lp1) on photoelectric conversion element”. On the other hand, a field indicated by “light intensity distribution (second polarized light Lp2) on photoelectric conversion element” indicates the light reception result of the second polarized light Lp2.

As is clear from FIG. 17, it can be seen that the condensing degree on the photoelectric conversion unit 20 is higher in a case where the light condensing unit 40 is provided (“with light condensing unit”) than in a case where the light condensing unit 40 is not provided (“without light condensing unit”).

That is, in each heat map indicated by “no light condensing unit” in FIG. 17, the range of the region (“non-blank region”) where polarized light with relatively strong intensity is received is relatively large. On the other hand, in each heat map indicated by “with light condensing unit” in FIG. 17, the range of the region (“non-blank region”) where polarized light with relatively strong intensity is received is relatively small. More specifically, the X direction size and the Y direction size of the non-blank region of “with the light condensing unit” are smaller than the X direction size and the Y direction size of the non-blank region of “without light condensing unit”, respectively.

As can be seen from FIG. 17, the image sensor 1 in which the planar shape of the central region portion 42 of the diffractive optical element 41 is a chamfered quadrangle (see FIG. 15) can exhibit substantially the same light condensing performance as the image sensor 1 in which the planar shape of the central region portion 42 is a rectangle (see FIG. 10).

Note that, although not illustrated in FIG. 17, the inventor of the present application also acquired a similar heat map in a case where the central region portion 42 of the diffractive optical element 41 (light condensing unit 40) has an oval planar shape (see FIG. 16).

As a result, in each heat map obtained in a case where the central region portion 42 had an oval shape, the range of the region (“non-blank region”) where polarized light with relatively strong intensity has been received has been relatively small.

More specifically, the X direction size and the Y direction size of the non-blank region in a case where the central region portion 42 has an oval shape are substantially the same as the X direction size and the Y direction size of the non-blank region in a case where the central region portion 42 has a chamfered quadrangle (see FIG. 15). That is, the X direction size and the Y direction size of the non-blank region in a case where the central region portion 42 has an oval shape are smaller than the X direction size and the Y direction size of the non-blank region of “no light condensing unit” described above, respectively.

### Fifth Structure Example

In the present structure example, the same or corresponding elements as those in the above-described first structure example are denoted by the same reference numerals, and a detailed description thereof will be omitted.

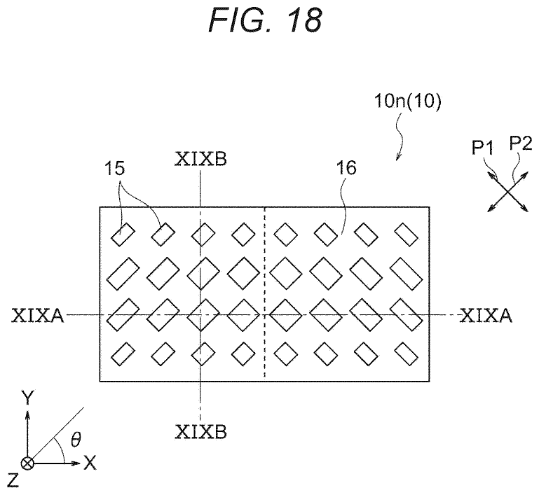

FIG. 18 is a cross-sectional view (XY cross section) of the polarization control unit 10 (particularly, the unit polarization control unit 10n) in a fifth structure example.

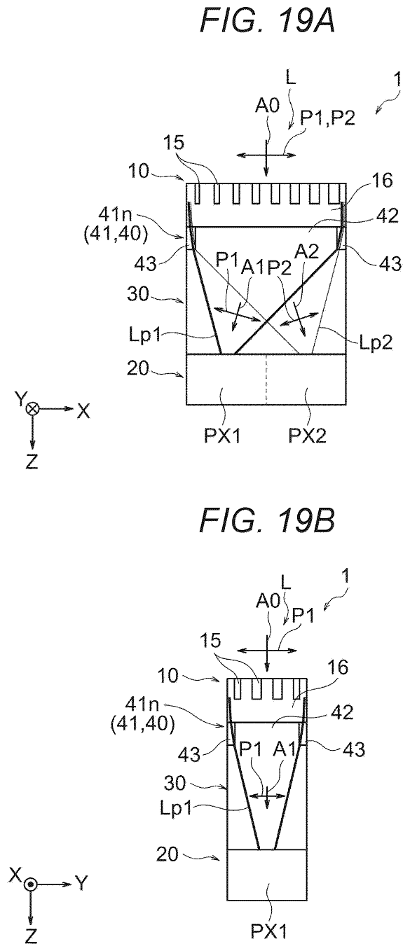

FIGS. 19A and 19B are partial cross-sectional views schematically illustrating the image sensor 1 of the fifth structure example, and illustrate a case where the incident light Lis perpendicularly incident on the image sensor 1 (particularly, the polarization control unit 10). FIG. 19A illustrates a cross section (XZ cross section) taken along the cross-sectional line XIXA-XIXA of FIG. 18. FIG. 19B illustrates a cross section (YZ cross section) taken along the cross-sectional line XIXB-XIXB in FIG. 18.

In the polarization control unit 10 of the present structure example, the plurality of meta-atoms 15 is two-dimensionally arranged in two directions (meta-atom array directions) oblique to the X direction and the Y direction.

In particular, the plurality of meta-atoms 15 included in each unit polarization control unit 10n includes a plurality of meta-atoms 15 in which sizes in two meta-atom array directions oblique to the X direction and the Y direction are different from each other.

As a result, the two polarized lights of the incident light L oscillating in two directions (the first polarized light oscillation direction P1 and the second polarized light oscillation direction P2) oblique to the X direction and the Y direction are separated by the polarization control unit 10 and emitted from the polarization control unit 10 as the first polarized light Lp1 and the second polarized light Lp2.

As described above, the polarization control unit 10 emits the first polarized light Lp1 and the second polarized light Lp2 oscillating in the first polarized light oscillation direction P1 and the second polarized light oscillation direction P2 that are oblique to the first array direction (X direction) and the second array direction (Y direction), respectively. Here, the first array direction and the second array direction are directions (X direction and Y direction) in which a plurality of pixels included in the photoelectric conversion unit 20 is arrayed.

The first polarized light oscillation direction P1 and the second polarized light oscillation direction P2 coincide with the meta-atom array direction and the size change direction in the XY plane of the plurality of meta-atoms 15 included in the unit polarization control unit 10n. However, a specific direction (inclination angle) of the meta-atom array direction in each unit polarization control unit 10n is not limited.

In the example illustrated in FIG. 18, the meta-atom array direction is set in two directions forming an angle θ of “45 degrees (and 225 degrees)” and “135 degrees (and 315 degrees)” with respect to the X direction on the XY plane.

Among the four sides forming the rectangular planar shape of each meta-atom 15, two sides (opposite sides) extend along one meta-atom array direction (0=45 degrees (and 225 degrees)), and the other two sides (opposite sides) extend along another meta-atom array direction (0=135 degrees (and 315 degrees)).

The plurality of meta-atoms 15 included in each unit polarization control unit 10n includes a plurality of meta-atoms 15 having different sizes in the meta-atom array direction (0=45 degrees and 135 degrees).

In this case, the oscillation directions of the first polarized light Lp1 and the second polarized light Lp2 separated by the polarization control unit 10 form angles θ of “45 degrees (and 225 degrees)” and “135 degrees (and 315 degrees)” with respect to the X direction on the XY plane.

Other configurations of the image sensor 1 of the present structure example are similar to those of the image sensor 1 of the above-described first structure example (FIGS. 8A to 10).

As described above, the plurality of meta-atoms 15 of the fifth structure example illustrated in FIGS. 18 to 19B is arrayed in a direction different from the array direction of the unit diffractive optical elements 41n and the array direction of the unit pixel group (that is, the X direction and the Y direction). In particular, the plurality of meta-atoms 15 included in each unit polarization control unit 10n includes meta-atoms 15 having different sizes in two meta-atom array directions.

As a result, the image sensor 1 can selectively separate polarized light oscillating in a direction different from the array direction of the unit diffractive optical elements 4 In and the array direction of the unit pixel groups (the X direction and the Y direction) from the incident light L and receive the polarized light.

As described above, the image sensor 1 can separate polarized light oscillating in an arbitrary direction from the incident light L and receive (detect) the polarized light according to the array and size of the plurality of meta-atoms 15 of the polarization control unit 10.

### Sixth Structure Example

In the present structure example, the same or corresponding elements as those in the above-described first structure example are denoted by the same reference numerals, and a detailed description thereof will be omitted.

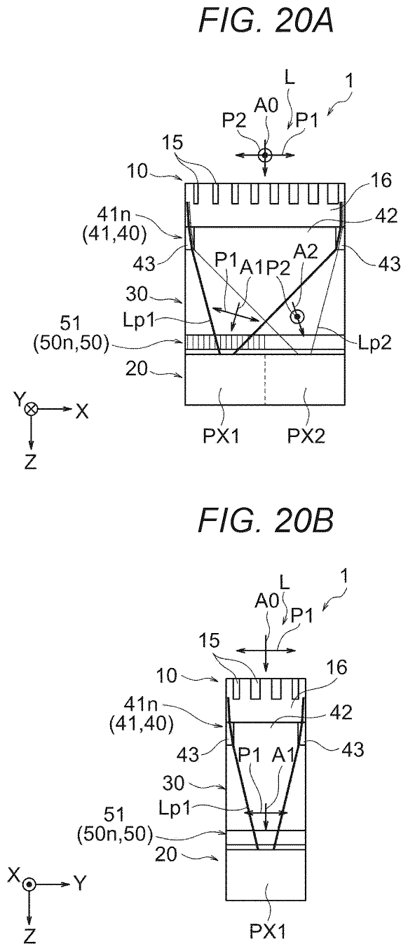

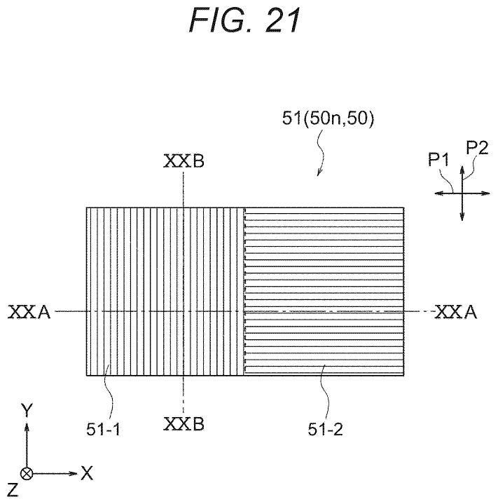

FIGS. 20A and 20B are partial cross-sectional views schematically illustrating the image sensor 1 of a sixth structure example, and illustrate a case where the incident light Lis perpendicularly incident on the image sensor 1 (particularly, the polarization control unit 10). FIG. 21 is a plan view illustrating an example of a wire grid polarizer 51 (additional polarizer 50).

FIG. 20A illustrates a cross section (XZ cross section) taken along the cross-sectional line XXA-XXA of FIG. 21. FIG. 20B illustrates a cross section (YZ cross section) taken along the cross-sectional line XXB-XXB of FIG. 21.

The image sensor 1 may include an additional polarizer 50 positioned between the light condensing unit 40 and the photoelectric conversion unit 20.

The additional polarizer 50 includes a plurality of unit additional polarizers 50n associated with each of the plurality of pixels. Each of the plurality of unit additional polarizers 50n selectively passes the polarized light corresponding to the associated pixel.

The additional polarizer 50 illustrated in FIGS. 20A to 21 includes a wire grid polarizer 51.

The specific configuration and material (composition) of the wire grid polarizer 51 are not limited.

The wire grid polarizer 51 can have a structure in which metal and a dielectric are periodically arrayed in a one-dimensional direction in a region (one pixel region) corresponding to each pixel. In this case, the material (composition) of the metal portion of the wire grid polarizer 51 can be appropriately selected from, for example, Au, Ag, Cu, Al, AlCu, and W. Furthermore, the material (composition) of the dielectric portion of the wire grid polarizer 51 can be appropriately selected from, for example, Si, α-Si, SiO₂, SiN, Si₃N₄, SiC, TiO₂, GaN, GaAs, and InP.

As described above, each pixel region of the wire grid polarizer 51 including the metal-dielectric periodic array structure transmits only the polarization component in the same direction as the periodic direction of the metal-dielectric.

In the example of the unit additional polarizer 50n illustrated in FIG. 21, a first wire grid polarizer region 51-1, which is a left pixel region, is positioned so as to cover the corresponding first polarization pixel PX1, and allows only the first polarized light Lp1 to be selectively transmitted and incident on the corresponding first polarization pixel PX1. On the other hand, a second wire grid polarizer region 51-2, which is a right pixel region of the unit additional polarizer 50n in FIG. 21, is positioned so as to cover the corresponding second polarization pixel PX2, and allows only the second polarized light Lp2 to be selectively transmitted and incident on the corresponding second polarization pixel PX2.

Other configurations of the image sensor 1 of the present structure example are similar to those of the image sensor 1 of the above-described first structure example (FIGS. 8A to 10).

As described above, in the image sensor 1 of the sixth structure example illustrated in FIGS. 20A to 21, the wire grid polarizer 51 (additional polarizer 50) is disposed between the diffractive optical element 41 (light condensing unit 40) and the photoelectric conversion unit 20. As a result, the polarized light from the polarization control unit 10 and the diffractive optical element 41 is incident on the wire grid polarizer 51, and only the polarized light transmitted through the wire grid polarizer 51 is incident on each pixel of the photoelectric conversion unit 20.

Each pixel region of the wire grid polarizer 51 basically does not allow transmission of polarized light that is not originally intended to be received by the associated pixel, and transmits only the originally intended polarization component.

As a result, only a desired linear polarization component associated with each pixel of the photoelectric conversion unit 20 can be more reliably made incident, and the purity of polarized light received by each pixel is increased.

### Seventh Structure Example

In the present structure example, the same or corresponding elements as those in the above-described sixth structure example are denoted by the same reference numerals, and a detailed description thereof will be omitted.

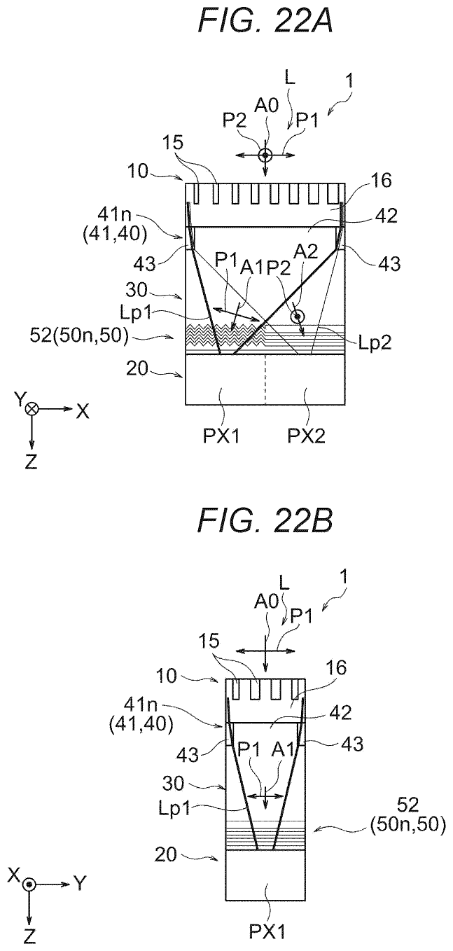

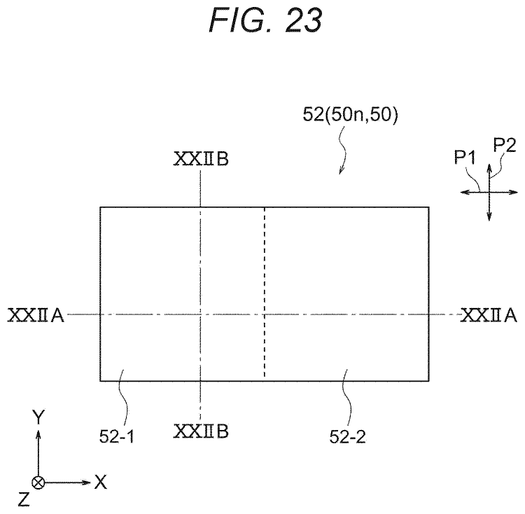

FIGS. 22A and 22B are partial cross-sectional views schematically illustrating the image sensor 1 of a seventh structure example, and illustrate a case where the incident light Lis perpendicularly incident on the image sensor 1 (particularly, the polarization control unit 10). FIG. 23 is a plan view illustrating an example of a photonic crystal polarizer 52 (additional polarizer 50).

FIG. 22A illustrates a cross section (XZ cross section) taken along the cross-sectional line XXIIA-XXIIA in FIG. 23. FIG. 22B illustrates a cross section (YZ cross section) taken along the cross-sectional line XXIIB-XXIIB of FIG. 23.

The additional polarizer 50 of the present structure example includes a photonic crystal polarizer 52 instead of the wire grid polarizer 51 (FIGS. 20A to 21) described above. The specific configuration and material (composition) of the photonic crystal polarizer 52 are not limited.

The photonic crystal polarizer 52 can have a structure in which a plurality of dielectric layers having different refractive indexes is periodically arrayed in a one-dimensional direction (Z direction) in a region (one pixel region) corresponding to each pixel. In this case, the material (composition) of the dielectric of the wire grid polarizer 51 can be appropriately selected from, for example, Si, α-Si, SiO₂, SiN, Si₃N₄, SiC, TiO₂, GaN, GaAs, InP, Ta₂O₃, and Nb₂O₅.

As described above, each pixel region of the photonic crystal polarizer 52 including the periodic array structure of the plurality of dielectrics having different refractive indexes transmits only the polarization component perpendicular to the uneven line.

A first photonic crystal polarizer region 52-1 which is a left pixel region of the photonic crystal polarizer 52 in FIG. 23 is positioned so as to cover the corresponding first polarization pixel PX1, and causes only the first polarized light Lp1 to be selectively transmitted and incident on the corresponding first polarization pixel PX1. On the other hand, a second photonic crystal polarizer region 52-2, which is a right pixel region of the unit additional polarizer 50n in FIG. 23, is positioned so as to cover the corresponding second polarization pixel PX2, and allows only the second polarized light Lp2 to be selectively transmitted and incident on the corresponding second polarization pixel PX2.

Other configurations of the image sensor 1 of the present structure example are similar to those of the image sensor 1 of the above-described sixth structure example (FIGS. 20A to 21).

As described above, in the image sensor 1 of the seventh structure example illustrated in FIGS. 22A to 23, the photonic crystal polarizer 52 (additional polarizer 50) is disposed between the diffractive optical element 41 (light condensing unit 40) and the photoelectric conversion unit 20.

Each pixel region of the photonic crystal polarizer 52 basically does not allow transmission of a polarization component that is not originally intended to be received by the associated pixel, and transmits only the originally intended polarization component. As a result, only a desired linear polarization component associated with each pixel of the photoelectric conversion unit 20 can be more reliably made incident, and the purity of polarized light received by each pixel is increased.

### Eighth Structure Example

In the present structure example, the same or corresponding elements as those in the above-described first structure example are denoted by the same reference numerals, and a detailed description thereof will be omitted.

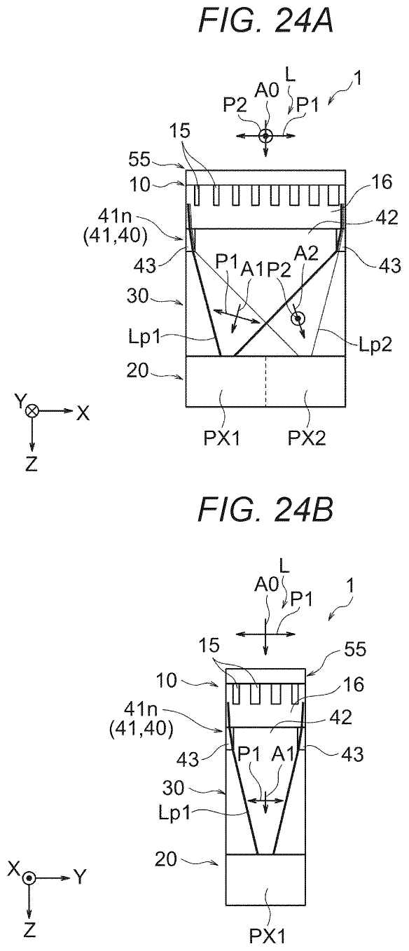

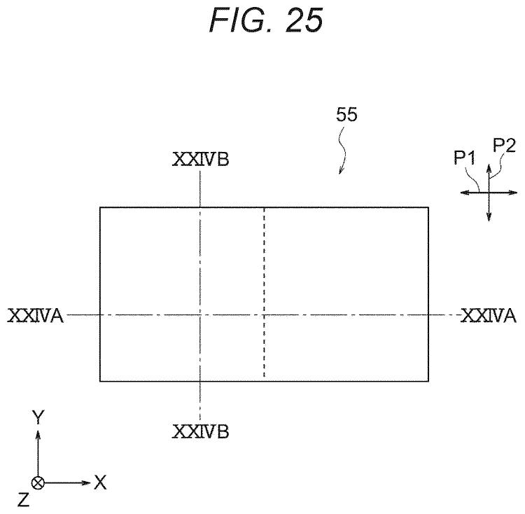

FIGS. 24A and 24B are partial cross-sectional views schematically illustrating the image sensor 1 of an eighth structure example, and illustrate a case where the incident light Lis perpendicularly incident on the image sensor 1 (particularly, the polarization control unit 10). FIG. 25 is a plan view illustrating an example of a band-pass filter 55 (for example, a color filter). FIG. 24A illustrates a cross section (XZ cross section) taken along the cross-sectional line XXIVA-XXIVA in FIG. 25. FIG. 24B illustrates a cross section (YZ cross section) taken along the cross-sectional line XXIVB-XXIVB in FIG. 25.

The image sensor 1 of the present structure example includes a band-pass filter 55, and the photoelectric conversion unit 20 receives light (polarized light) having passed through the band-pass filter 55.

The band-pass filter 55 selectively transmits only a desired wavelength band component. The transmission wavelength range of the band-pass filter 55 is not limited and can be arbitrarily set. For example, a color filter that selectively transmits a wavelength (light) in the visible light region or an infrared transmitting filter that selectively transmits infrared rays can be used as the band-pass filter 55.

The transmission wavelength range of the band-pass filter 55 may be adaptively determined according to the application of the image sensor 1 or the like. For example, the image sensor 1 used for monitoring a defect such as a scratch of a product (for example, food or medicine) may include, as the band-pass filter 55, a filter (infrared transmitting filter) that does not transmit visible light but transmits infrared light. In this case, the image sensor 1 can acquire an infrared image of a product from which a visible light component that can hinder the discovery of a defect such as a scratch is removed.

Note that light components (wavelength components) that do not pass through the band-pass filter 55 are reflected by the surface of the band-pass filter 55 or absorbed by the band-pass filter 55.

The band-pass filter 55 illustrated in FIGS. 24A to 25 is provided outside the polarization control unit 10 (that is, on the opposite side to the photoelectric conversion unit 20 via the polarization control unit 10) so as to cover the entire plurality of pixels included in the photoelectric conversion unit 20. The band-pass filter 55 is disposed over the entire range (that is, a region covering two pixels) corresponding to the unit pixel group (that is, one first polarization pixel PX1 and one second polarization pixel PX2) of the photoelectric conversion unit 20.

The specific configuration and material (composition) of the band-pass filter 55 are not limited, and the band-pass filter 55 may include, for example, a dielectric material or an absorbent material.

Other configurations of the image sensor 1 of the present structure example are similar to those of the image sensor 1 of the above-described first structure example (FIGS. 8A to 10).

As described above, in the image sensor 1 of the eighth structure example illustrated in FIGS. 24A to 25, the polarized light transmitted through the band-pass filter 55 is incident on the photoelectric conversion unit 20. In other words, polarized light that does not pass through the band-pass filter 55 is not incident on the photoelectric conversion unit 20.

As a result, only polarized light in a desired wavelength range can be more reliably incident on each pixel of the photoelectric conversion unit 20, and the purity of the wavelength of polarized light received by each pixel is increased.

Note that the installation position (particularly, the position in the Z direction) of the band-pass filter 55 is not limited to the example illustrated in FIGS. 24A and 24B.

As illustrated in FIGS. 24A and 24B, the band-pass filter 55 may be provided on the subject side of the polarization control unit 10. In this case, the incident light L before the polarized light is separated by the polarization control unit 10 is incident on the band-pass filter 55, and a desired wavelength band component in the incident light L passes through the band-pass filter 55.

Furthermore, the band-pass filter 55 may be provided at an arbitrary position between the polarization control unit 10 and the photoelectric conversion unit 20. For example, the band-pass filter 55 may be provided between the polarization control unit 10 and the diffractive optical element 41 (light condensing unit 40) or between the diffractive optical element 41 (light condensing unit 40) and the photoelectric conversion unit 20. In this case, the polarized light separated from the incident light L by the polarization control unit 10 is incident on the band-pass filter 55, and a desired wavelength band component in the polarized light is transmitted through the band-pass filter 55.

### Ninth Structure Example

In the present structure example, the same or corresponding elements as those in the above-described first structure example are denoted by the same reference numerals, and a detailed description thereof will be omitted.

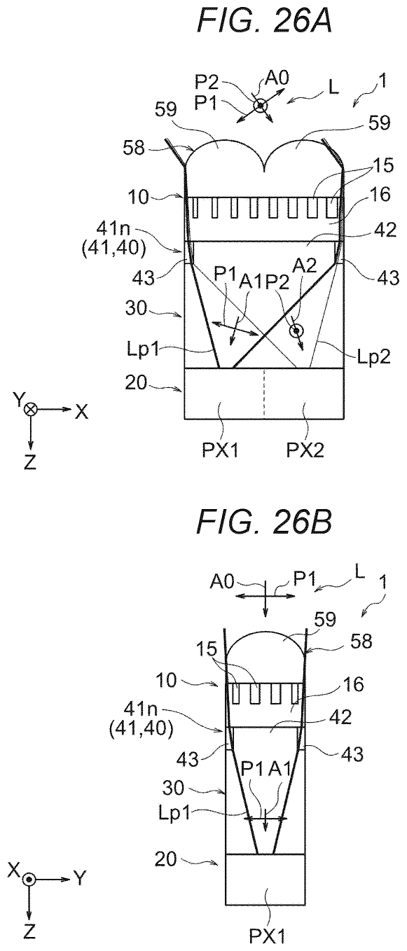

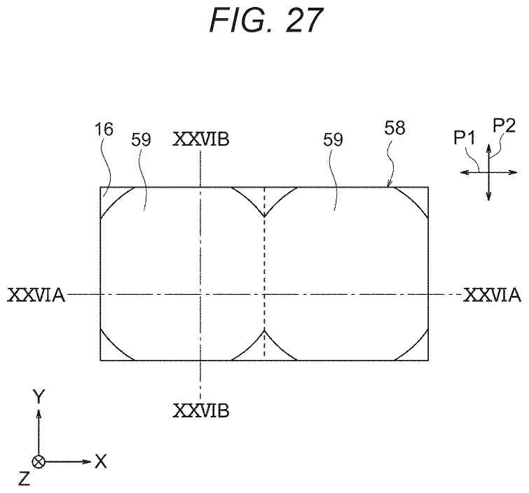

FIGS. 26A and 26B are partial cross-sectional views schematically illustrating the image sensor 1 of the ninth structure example, illustrating a case where the incident light L is obliquely incident on the image sensor 1 (particularly, on-chip lens 58). FIG. 27 is a plan view illustrating an example of the on-chip lens 58 of the ninth structure example.

FIG. 26A illustrates a cross section (XZ cross section) taken along the cross-sectional line XXVIA-XXVIA of FIG. 27. FIG. 26B illustrates a cross section (YZ cross section) taken along the cross-sectional line XXVIB-XXVIB of FIG. 27.

The image sensor 1 of the present structure example is provided with an on-chip lens 58 including a plurality of microlenses 59. The incident light L passes through the microlens 59 and then enters the polarization control unit 10.

The on-chip lens 58 illustrated in FIGS. 26A to 27 is provided outside the polarization control unit 10 (that is, on the opposite side to the photoelectric conversion unit 20 via the polarization control unit 10) so as to cover the plurality of pixels included in the photoelectric conversion unit 20.

The on-chip lens 58 is disposed over the range (that is, a region covering two pixels) corresponding to the unit pixel group (that is, one first polarization pixel PX1 and one second polarization pixel PX2) of the photoelectric conversion unit 20. In particular, in the present structure example, one microlens 59 is allocated to individual pixel (each pixel) of the photoelectric conversion unit 20, and one microlens 59 is disposed in one pixel region of the on-chip lens 58.

The specific configuration and material (composition) of the on-chip lens 58 are not limited. The material (composition) of the on-chip lens 58 can be appropriately selected from, for example, dielectric Si, α-Si, SiO₂, SiN, Si₃N₄, SiC, TiO₂, GaN, GaAs, and InP.

Other configurations of the image sensor 1 of the present structure example are similar to those of the image sensor 1 of the above-described first structure example (FIGS. 8A to 10).

As described above, in the image sensor 1 of the ninth structure example illustrated in FIGS. 26A to 27, the on-chip lens 58 is provided on the incident side of the polarization control unit 10. Therefore, the incident light L subjected to pupil correction by the on-chip lens 58 enters the polarization control unit 10.

Therefore, even if the incident angle of the incident light L with respect to the image sensor 1 (particularly, the on-chip lens 58) is large, the incident angle of the incident light L with respect to the polarization control unit 10 (the plurality of meta-atoms 15) is brought close to 0 degrees by the on-chip lens 58.

As a result, even if the incident light Lis obliquely incident on the image sensor 1 (particularly, the on-chip lens 58), the condensing position (light-condensed spot) on the corresponding pixel of each polarized light emitted from the polarization control unit 10 is brought close to the center of the corresponding pixel, and leakage of light (polarized light) between adjacent pixels can be reduced. [Tenth Structure Example]

In the present structure example, the same or corresponding elements as those in the above-described ninth structure example are denoted by the same reference numerals, and a detailed description thereof will be omitted.

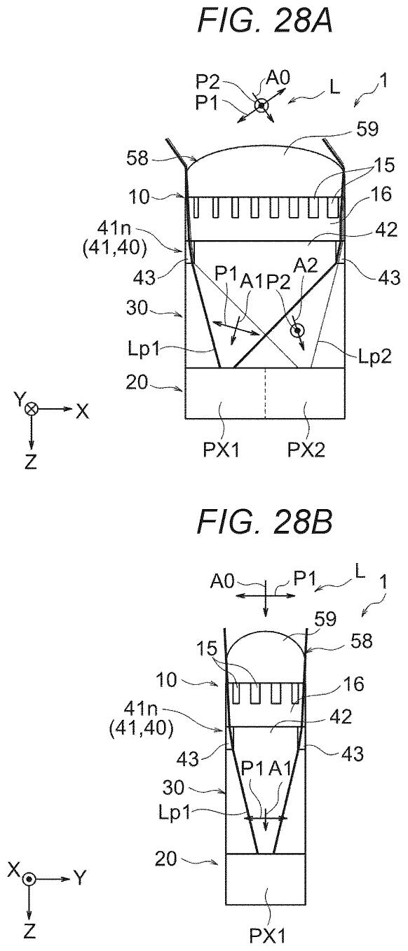

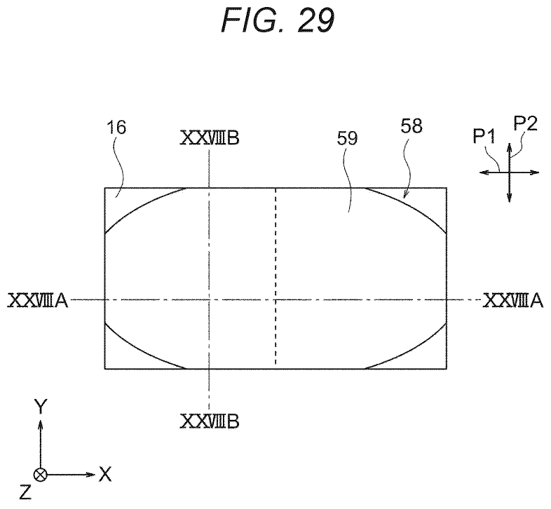

FIGS. 28A and 28B are partial cross-sectional views schematically illustrating the image sensor 1 of the tenth structure example, illustrating a case where the incident light L is obliquely incident on the image sensor 1 (particularly, on-chip lens 58). FIG. 29 is a plan view illustrating an example of an on-chip lens 58 of the tenth structure example.

FIG. 28A illustrates a cross section (XZ cross section) taken along the cross-sectional line XXVIIIA-XXVIIIA in FIG. 29. FIG. 28B illustrates a cross section (YZ cross section) taken along the cross-sectional line XXVIIIB-XXVIIIB of FIG. 29.

In the on-chip lens 58 of the present structure example, each microlens 59 is associated with two or more pixels, and a plurality of polarized lights in the incident light L passing through each microlens 59 is incident on the associated two or more pixels.

In the on-chip lens 58 illustrated in FIGS. 28A to 29, each microlens 59 is disposed over two pixel regions (that is, regions covering two pixels) corresponding to a unit pixel group (that is, one first polarization pixel PX1 and one second polarization pixel PX2).

Other configurations of the image sensor 1 of the present structure example are similar to those of the image sensor 1 of the above-described first structure example (FIGS. 8A to 10).

As described above, also in the image sensor 1 of the tenth structure example illustrated in FIGS. 28A to 29, the on-chip lens 58 is provided on the incident side of the polarization control unit 10. Therefore, the incident light L subjected to pupil correction by the on-chip lens 58 enters the polarization control unit 10. As a result, even if the incident light Lis obliquely incident on the image sensor 1, the condensing position on the corresponding pixel of each polarized light emitted from the polarization control unit 10 is brought close to the center of the corresponding pixel, and leakage of light between adjacent pixels can be reduced.

### Eleventh Structure Example

In the present structure example, the same or corresponding elements as those in the above-described first structure example are denoted by the same reference numerals, and a detailed description thereof will be omitted.

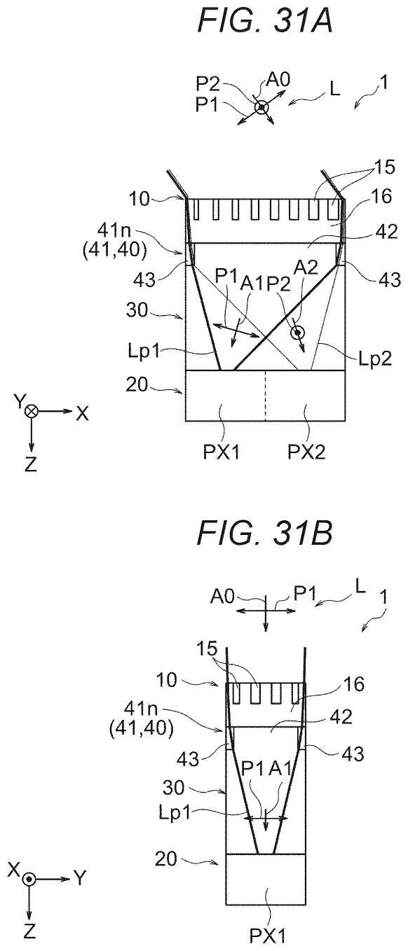

FIG. 30 is a cross-sectional view (XY cross section) of the polarization control unit 10 (particularly, the unit polarization control unit 10n) in the eleventh structure example. FIGS. 31A and 31B are partial cross-sectional views schematically illustrating the image sensor 1 of the eleventh structure example, and illustrates a case where the incident light Lis obliquely incident on the image sensor 1 (particularly, the polarization control unit 10).

FIG. 31A illustrates a cross section (XZ cross section) taken along the cross-sectional line XXXIA-XXXIA in FIG. 30. FIG. 31B illustrates a cross section (XZ cross section) taken along the cross-sectional line XXXIB-XXXIB of FIG. 30.

In the present structure example, the two polarized lights (the first polarized light Lp1 and the second polarized light Lp2) selectively emitted from each unit polarization control unit 10n oscillate in the first polarized light oscillation direction P1 and the second polarized light oscillation direction P2, respectively. Then the plurality of meta-atoms 15 included in each unit polarization control unit 10n includes a first reference meta-atom (first reference fine structure) 15 A having a maximum length in the first polarized light oscillation direction P1 and a second reference meta-atom (second reference fine structure) 15B having a maximum length in the second polarized light oscillation direction P2. Here, the direction indicating the maximum length of the first reference meta-atom 15A is substantially a direction in which the oscillation direction (first polarized light oscillation direction P1) of the first polarized light Lp1 in the incident light L when incident (or immediately before incident) on the unit polarization control unit 10n is indicated on the XY plane. Furthermore, the direction indicating the maximum length of the second reference meta-atom 15B is substantially a direction in which the oscillation direction (second polarized light oscillation direction P2) of the second polarized light Lp2 in the incident light L when incident (or immediately before incident) on the unit polarization control unit 10n is indicated on the XY plane.

The plurality of meta-atoms 15 included in each unit polarization control unit 10n includes the plurality of meta-atoms 15 in which the length in the direction of the first polarized light gradually decreases with increasing distance from the first reference meta-atom 15A. Furthermore, the plurality of meta-atoms 15 included in each unit polarization control unit 10n includes the plurality of meta-atoms 15 in which the length of the second polarized light oscillation direction P2 gradually decreases with increasing distance from the second reference meta-atom 15B.

In the example illustrated in FIGS. 30 to 31B, the first reference meta-atom 15A has the maximum length in the X direction corresponding to the first polarized light oscillation direction P1, and the second reference meta-atom 15B has the maximum length in the Y direction corresponding to the second polarized light oscillation direction P2. Then the length in the X direction decreases as the distance from the first reference meta-atom 15A increases for all the meta-atoms 15 included in the unit polarization control unit 10n. Similarly, the length in the Y direction decreases as the distance from the second reference meta-atom 15B increases for all the meta-atoms 15 included in the unit polarization control unit 10n.

The unit polarization control unit 10n illustrated in FIGS. 30 to 31B is associated with two pixels (the first polarization pixel PX1 and the second polarization pixel PX2) among the plurality of pixels included in the photoelectric conversion unit 20, and is provided so as to cover the two pixels.

The first polarized light Lp1 emitted from each unit polarization control unit 10n is condensed on one (first polarization pixel PX1) of the two pixels associated with each other via the diffractive optical element 41 (light condensing unit 40). On the other hand, the second polarized light Lp2 emitted from each unit polarization control unit 10n is condensed on the another one (second polarization pixel PX2) of the two pixels associated with each other via the diffractive optical element 41 (light condensing unit 40).

In the example illustrated in FIGS. 30 to 31B, the first reference meta-atom 15A is disposed in a region covering one (first polarization pixel PX1) of two associated pixels in each unit polarization control unit 10n. Furthermore, in each unit polarization control unit 10n, the second reference meta-atom 15B is disposed in a region covering the another one (second polarization pixel PX2) of the two associated pixels.

Other configurations of the image sensor 1 of the present structure example are similar to those of the image sensor 1 of the above-described first structure example (FIGS. 8A to 10).

As described above, in the unit polarization control unit 10n illustrated in FIGS. 30 to 31B, the size of each meta-atom 15 in the direction corresponding to the polarized light oscillation directions P1 and P2 changes densely according to the distance from the reference meta-atoms 15A and 15B. Since the phase delay amount of the polarized light transmitted through the polarization control unit 10 changes according to the size of the meta-atom 15 in the direction corresponding to the oscillation direction of the polarized light, the phase delay distribution of the polarized light according to the size distribution of the meta-atom 15 is obtained.

Each unit polarization control unit 10n having such a structure separates desired polarized lights P1 and P2 from the incident light L, and exerts an exit pupil correction function to adjust the emission directions of the desired polarized lights P1 and P2. As a result, the desired polarized lights P1 and P2 separated from the incident light L are more effectively condensed on the corresponding pixels, and leakage of the polarized lights P1 and P2 between the adjacent pixels is more effectively suppressed.

Note that the exit pupil correction is correction for causing the polarized lights P1 and P2 in the incident light L to enter the corresponding pixels even when the incident angle of the incident light L is large. Therefore, the optimum degree of the exit pupil correction by each unit polarization control unit 10n changes according to the distance of the pixel (unit pixel group) associated with each unit polarization control unit 10n from the center (position through which the optical axis passes) of the photoelectric conversion unit 20. On the other hand, the degree of the exit pupil correction exhibited in each unit polarization control unit 10n changes at least according to the positions of the first reference meta-atom 15A and the second reference meta-atom 15B in each unit polarization control unit 10n.

Therefore, it is possible to promote the optimization of the condensing position in each pixel by changing the positions of the first reference meta-atom 15A and the second reference meta-atom 15B in each unit polarization control unit 10n according to the distance from the center of the photoelectric conversion unit 20 to the corresponding pixel.

For example, the position of the first reference meta-atom 15A in each unit polarization control unit 10n may be separated farther from the position corresponding to the center of the corresponding first polarization pixel PX1 as the distance between the corresponding pixel and the center of the photoelectric conversion unit 20 increases. Similarly, the position of the second reference meta-atom 15B in each unit polarization control unit 10n may be separated farther from the position corresponding to the center of the corresponding second polarization pixel PX2 as the distance between the corresponding pixel and the center of the photoelectric conversion unit 20 increases.

Furthermore, the position of the first reference meta-atom 15A in each unit polarization control unit 10n may be separated farther from the position corresponding to the center of the corresponding first polarization pixel PX1 as the incident angle of the incident light L with respect to each unit polarization control unit 10n increases. Similarly, the position of the second reference meta-atom 15B in each unit polarization control unit 10n may be separated farther from the position corresponding to the center of the corresponding second polarization pixel PX2 as the incident angle of the incident light L with respect to each unit polarization control unit 10n increases.

### Twelfth Structure Example

In the present structure example, the same or corresponding elements as those in the above-described first structure example are denoted by the same reference numerals, and a detailed description thereof will be omitted.

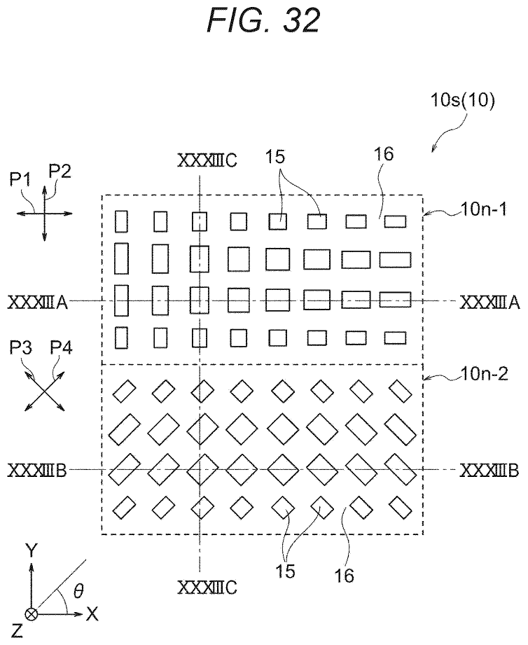

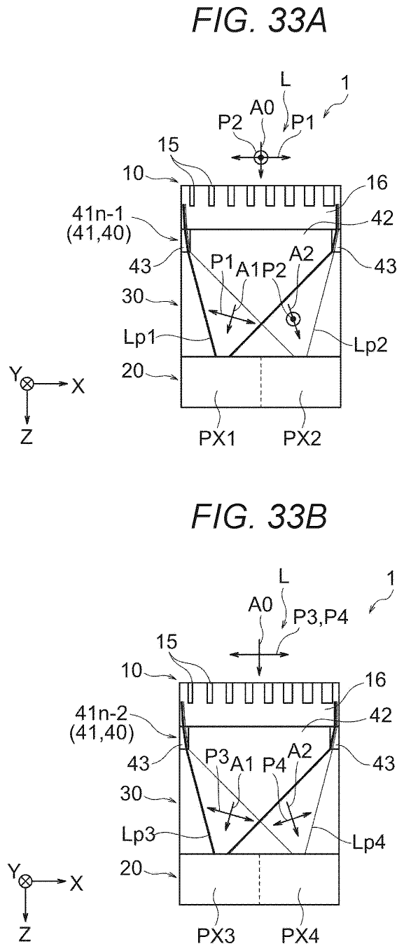

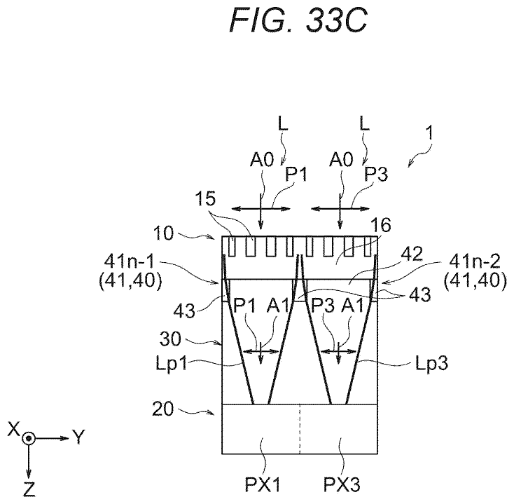

FIG. 32 is a cross-sectional view (XY cross section) of the polarization control unit 10 (particularly, a sub-unit polarization control unit 10s) in the twelfth structure example. FIGS. 33A to 33C are partial cross-sectional views schematically illustrating the image sensors 1 of the twelfth structure example, and illustrates a case where the incident light Lis perpendicularly incident on the image sensor 1 (particularly, the polarization control unit 10).

FIG. 33A illustrates a cross section (XZ cross section) taken along the cross-sectional line XXXIIIA-XXXIIIA in FIG. 32. FIG. 33B illustrates a cross section (XZ cross section) taken along the cross-sectional line XXXIIIB-XXXIIIB of FIG. 32. FIG. 33C illustrates a cross section (YZ cross section) taken along the cross-sectional line XXXIIIC-XXXIIIC of FIG. 32.

The plurality of unit polarization control units 10n included in the polarization control unit 10 of the present structure example includes a plurality of types of unit polarization control units that separates and emits polarized light oscillating in different directions.

In the examples illustrated in FIGS. 32 to 33C, a first unit polarization control unit 10n-1 and a second unit polarization control unit 10n-2 are provided as the plurality of types of unit polarization control units 10n.

The first unit polarization control unit 10n-1 selectively emits the first polarized light Lp1 and the second polarized light Lp2 in the incident light L. The second unit polarization control unit 10n-2 selectively emits a third polarized light Lp3 and a fourth polarized light Lp4 in the incident light L. The first polarized light Lp1 to the fourth polarized light Lp4 oscillate in different directions.

The sub-unit polarization control units 10s including one first unit polarization control unit 10n-1 and one second unit polarization control unit 10n-2 adjacent in the Y direction are two-dimensionally arrayed in the X direction and the Y direction, thereby configuring the polarization control unit 10 illustrated in FIGS. 32 to 33C. In other words, the polarization control unit 10 of the present structure example is divided into a plurality of sub-unit polarization control units 10s arrayed two-dimensionally.

Each unit polarization control unit 10n (each of the first unit polarization control unit 10n-1 and the second unit polarization control unit 10n-2) is disposed over regions (two pixel regions) corresponding to two pixels of the photoelectric conversion unit 20 and covers the two pixels. Therefore, the sub-unit polarization control unit 10s including the two unit polarization control units 10n is disposed over regions (four pixel regions) corresponding to four pixels of the photoelectric conversion unit 20 and covers the four pixels.

The diffractive optical element 41 (light condensing unit 40) includes a plurality of unit diffractive optical elements 41n (unit light condensing unit). Each of the unit diffractive optical elements 4 In condenses each of the two polarized lights emitted from the associated unit polarization control unit 10n on an adjacent pixel.

The plurality of unit diffractive optical elements 41n (unit light condensing units) of the present structure example includes a plurality of first unit diffractive optical elements 41n-1 (first unit light condensing units) and a plurality of second unit diffractive optical elements 41n-2 (second unit light condensing units). Each of the first unit diffractive optical elements 41n-1 condenses the first polarized light and the second polarized light from the corresponding first unit polarization control unit 10n-1 on the adjacent pixels (the first polarization pixel PX1 and the second polarization pixel PX2). Each of the second unit diffractive optical elements 41n-2 condenses the third polarized light and the fourth polarized light from the corresponding second unit polarization control unit 10n-2 on the adjacent pixels (a third polarization pixel PX3 and a fourth polarization pixel PX4). Note that the first unit diffractive optical element 41n-1 and the second unit diffractive optical element 41n-2 condense polarized lights different from each other, but basically have the same structure.

In the examples illustrated in FIGS. 32 to 33C, the first unit polarization control unit 10n-1 has the same structure as the unit polarization control unit 10n of the first structure example illustrated in FIG. 9 described above, and the second unit polarization control unit 10n-2 has the same structure as the unit polarization control unit 10n of the fifth structure example illustrated in FIG. 18 described above.

Therefore, the first unit polarization control unit 10n-1 illustrated in FIGS. 32 to 33C separates and emits the first polarized light Lp1 and the second polarized light Lp2 in the oscillation directions (the first polarized light oscillation direction P1 and the second polarized light oscillation direction P2) forming angles θ of 0 degrees and 90 degrees with respect to the X direction on the XY plane. Furthermore, the second unit polarization control unit 10n-2 illustrated in FIGS. 32 to 33C separates and emits the third polarized light Lp3 and the fourth polarized light Lp4 in the oscillation directions (the third polarized light oscillation direction P3 and the fourth polarized light oscillation direction P4) forming angles θ of 45 degrees and 135 degrees with respect to the X direction on the XY plane.

Other configurations of the image sensor 1 of the present structure example are similar to those of the image sensor 1 of the above-described first structure example (FIGS. 8A to 10).

As described above, in the image sensor 1 of the twelfth structure example illustrated in FIGS. 32 to 33C, the sub-unit polarization control unit 10s that selectively separates the first polarized light Lp1 to the fourth polarized light Lp4 from the incident light L and emits the first polarized light Lp1 to the fourth polarized light Lp4 is provided.

Therefore, in the image sensor 1 capable of receiving and detecting the four polarized lights Lp1 to Lp4, all of the four polarized lights Lp1 to Lp4 can be highly condensed in the corresponding pixels PX1 to PX4.

### [Modifications]

It should be noted that the embodiment and modifications disclosed in the present specification are illustrative only in all respects and are not to be construed as limiting. The above-described embodiment and modifications can be omitted, replaced, and changed in various forms without departing from the scope and spirit of the appended claims. For example, the above-described embodiments and modifications may be combined in whole or in part, and other embodiments may be combined with the above-described embodiments or modifications. Furthermore, the effects of the present disclosure described in the present description are merely exemplification, and other effects may be provided.

For example, the image sensor 1 of the third structure example to the twelfth structure example (FIGS. 14A to 33C) may include a refraction type light condensing unit 40 (see FIGS. 11A, 11B, and 13) instead of the diffractive type light condensing unit 40 (diffractive optical element 41).

A technical category embodying the above technical idea is not limited. For example, the above-described technical idea may be embodied by a computer program for causing a computer to execute one or a plurality of procedures (steps) included in a method of manufacturing or using the above-described device. Furthermore, the above-described technical idea may be embodied by a computer-readable non-transitory recording medium in which such a computer program is recorded.

[Supplementary note]

The present disclosure can also have the following configurations.

### [Item 1]

A photodetection device including:
a polarization control unit that includes a plurality of fine structures arrayed two-dimensionally and selectively emits a plurality of polarized lights in incident light;
a photoelectric conversion unit that includes a plurality of pixels receiving the plurality of polarized lights; and
a light condensing unit that is positioned between the polarization control unit and the photoelectric conversion unit and condenses the plurality of polarized lights on respectively corresponding pixels.

### [Item 2]

The photodetection device according to Item 1, in which
the light condensing unit includes a diffractive optical element that condenses the plurality of polarized lights on respectively corresponding pixels using diffraction.

### [Item 3]

The photodetection device according to Item 1 or 2, in which
the light condensing unit includes a lens that condenses the plurality of polarized lights on respectively corresponding pixels using refraction.

[Item 4]

The photodetection device according to Item 2, in which
the diffractive optical element includes a plurality of unit diffractive optical elements, and
each of the plurality of unit diffractive optical elements includes a central region portion that transmits the plurality of polarized lights and a peripheral region portion that exhibits a refractive index different from a refractive index of the central region portion.

### [Item 5]

The photodetection device according to Item 4, in which
the polarization control unit includes a structure peripheral portion that supports the plurality of fine structures and has a smaller refractive index than the plurality of fine structures, and
the central region portion and the structure peripheral portion include a same material.

### [Item 6]

The photodetection device according to Item 4 or 5, in which
the central region portion has a quadrangular, chamfered quadrangular, or oval planar shape.

### [Item 7]

The photodetection device according to any one of Items 1 to 6, in which
the plurality of pixels is arranged along a first array direction and a second array direction perpendicular to the first array direction,
the polarization control unit emits a first polarized light and a second polarized light in the incident light, the first polarized light oscillating in the first array direction and the second polarized light oscillating in the second array direction, and
the light condensing unit condenses the first polarized light and the second polarized light on respectively corresponding pixels.

### [Item 8]

The photodetection device according to any one of Items 1 to 7, in which
the plurality of pixels is arranged along a first array direction and a second array direction perpendicular to the first array direction,
the polarization control unit emits a first polarized light and a second polarized light obtained from the incident light, the first polarized light and the second polarized light oscillating in a direction oblique to the first array direction and the second array direction, and
the light condensing unit condenses the first polarized light and the second polarized light on respectively corresponding pixels.

### [Item 9]

The photodetection device according to any one of Items 1 to 8, including:
an additional polarizer that is positioned between the light condensing unit and the photoelectric conversion unit, in which
the additional polarizer includes a plurality of unit additional polarizers associated with each of the plurality of pixels, and
each of the plurality of unit additional polarizers selectively passes a polarized light corresponding to an associated pixel.

### [Item 10]

The photodetection device according to Item 9, in which the additional polarizer includes a wire grid polarizer.

### [Item 11]

The photodetection device according to Item 9, in which the additional polarizer includes a photonic crystal polarizer.

### [Item 12]

The photodetection device according to any one of Items 1 to 11, including:
a band-pass filter, in which
the photoelectric conversion unit receives light that has passed through the band-pass filter.

### [Item 13]

The photodetection device according to any one of Items 1 to 12, including:
an on-chip lens including a plurality of microlenses, in which
the incident light is incident on the polarization control unit after passing through the on-chip lens.

### [Item 14]

The photodetection device according to Item 13, in which
each of the plurality of microlenses is associated with two or more pixels, and
the plurality of polarized lights in the incident light having passed through each of the plurality of microlenses is incident on two or more pixels associated with each other.

### [Item 15]

The photodetection device according to any one of Items 1 to 14, in which
the polarization control unit includes a plurality of unit polarization control units,
each of the plurality of unit polarization control units selectively emits a first polarized light oscillating in a first polarized light oscillation direction and a second polarized light oscillating in a second polarized light oscillation direction in the incident light,
a plurality of fine structures included in each of the plurality of unit polarization control units includes a first reference fine structure having a maximum length in the first polarized light oscillation direction, and a plurality of fine structures in which a length in the first polarized light oscillation direction gradually decreases as a distance from the first reference fine structure increases, and
a plurality of fine structures included in each of the plurality of unit polarization control units includes a second reference fine structure having a maximum length in the second polarized light oscillation direction, and a plurality of fine structures in which a length in the second polarized light oscillation direction gradually decreases as a distance from the second reference fine structure increases.

### [Item 16]

The photodetection device according to Item 15, in which
each of the plurality of unit polarization control units is associated with two pixels among the plurality of pixels,
the first polarized light emitted from each of the plurality of unit polarization control units is condensed on one of the two pixels associated with each other via the light condensing unit, and
the second polarized light emitted from each of the plurality of unit polarization control units is condensed on another one of the two pixels associated with each other via the light condensing unit.

### [Item 17]

The photodetection device according to any one of Items 1 to 16, in which
the polarization control unit includes a plurality of unit polarization control units that selectively emits two polarized lights in the incident light,
each of the plurality of unit polarization control units covers a region corresponding to two pixels of the photoelectric conversion unit, and
the light condensing unit includes a plurality of unit light condensing units that condenses each of the two polarized lights on an adjacent pixel.

### [Item 18]

The photodetection device according to Item 17, in which
the plurality of unit polarization control units includes:
   a plurality of first unit polarization control units that selectively emits a first polarized light and a second polarized light in the incident light; and
   a plurality of second unit polarization control units that selectively emits a third polarized light and a fourth polarized light in the incident light, and
the plurality of unit light condensing units includes:
   a plurality of first unit light condensing units that condenses the first polarized light and the second polarized light on respectively adjacent pixels; and
   a plurality of second unit light condensing units that condenses the third polarized light and the fourth polarized light on respectively adjacent pixels.

### [Item 19]

The photodetection device according to Item 18, in which
the polarization control unit includes a plurality of sub-unit polarization control units, and
each of the plurality of sub-unit polarization controls includes the first unit polarization control unit and the second unit polarization control unit.

### REFERENCE SIGNS LIST

1 Image sensor
10 Polarization control unit
10n Unit polarization control unit
10n-1 First unit polarization control unit
10n-2 Second unit polarization control unit
10s Sub-unit polarization control unit
15 Meta-atom
15A First reference meta-atom
15B Second reference meta-atom
16 Structure peripheral portion
20 Photoelectric conversion unit
30 Waveguide path
40 Light condensing unit
41 Diffractive optical element
41n Unit diffractive optical element
41n-1 First unit diffractive optical element
41n-2 Second unit diffractive optical element
42 Central region portion
43 Peripheral region portion
45 Condenser lens
45n Unit condenser lens
50 Additional polarizer
50n Unit additional polarizer
51 Wire grid polarizer
51-1 First wire grid polarizer region
51-2 Second wire grid polarizer region
52 Photonic crystal polarizer
52-1 First photonic crystal polarizer region
52-2 Second photonic crystal polarizer region
55 Band-pass filter
58 On-chip lens
59 Microlens
A0 Incident direction
C1 First reference position
C2 Second reference position
E1 Exit pupil
E2 Exit pupil
L Incident light
La Front incident light
Lb Inclined incident light
Lp1 First polarized light
Lp2 Second polarized light
Lp3 Third polarized light
Lp4 Fourth polarized light
OB Subject
OP Optical system
P1 First polarized light oscillation direction
P2 Second polarized light oscillation direction
P3 Third polarized light oscillation direction
P4 Fourth polarized light oscillation direction
PX Pixel
PX1 First polarization pixel
PX2 Second polarization pixel
PX3 Third polarization pixel
PX4 Fourth polarization pixel
Sd Shift amount

What is claimed is:

1. A photodetection device, comprising:
a polarization control unit that includes a plurality of fine structures arrayed two-dimensionally and selectively emits a plurality of polarized lights in incident light;
a photoelectric conversion unit that includes a plurality of pixels receiving the plurality of polarized lights; and
a light condensing unit that is positioned between the polarization control unit and the photoelectric conversion unit and condenses the plurality of polarized lights on respectively corresponding pixels.

2. The photodetection device according to claim 1, wherein
the light condensing unit includes a diffractive optical element that condenses the plurality of polarized lights on respectively corresponding pixels using diffraction.

3. The photodetection device according to claim 1, wherein
the light condensing unit includes a lens that condenses the plurality of polarized lights on respectively corresponding pixels using refraction.

4. The photodetection device according to claim 2, wherein
the diffractive optical element includes a plurality of unit diffractive optical elements, and
each of the plurality of unit diffractive optical elements includes a central region portion that transmits the plurality of polarized lights and a peripheral region portion that exhibits a refractive index different from a refractive index of the central region portion.

5. The photodetection device according to claim 4, wherein
the polarization control unit includes a structure peripheral portion that supports the plurality of fine structures and has a smaller refractive index than the plurality of fine structures, and
the central region portion and the structure peripheral portion include a same material.

6. The photodetection device according to claim 4, wherein
the central region portion has a quadrangular, chamfered quadrangular, or oval planar shape.

7. The photodetection device according to claim 1, wherein
the plurality of pixels is arranged along a first array direction and a second array direction perpendicular to the first array direction,
the polarization control unit emits a first polarized light and a second polarized light in the incident light, the first polarized light oscillating in the first array direction and the second polarized light oscillating in the second array direction, and
the light condensing unit condenses the first polarized light and the second polarized light on respectively corresponding pixels.

8. The photodetection device according to claim 1, wherein
the plurality of pixels is arranged along a first array direction and a second array direction perpendicular to the first array direction,
the polarization control unit emits a first polarized light and a second polarized light obtained from the incident light, the first polarized light and the second polarized light oscillating in a direction oblique to the first array direction and the second array direction, and
the light condensing unit condenses the first polarized light and the second polarized light on respectively corresponding pixels.

9. The photodetection device according to claim 1, further comprising:
an additional polarizer that is positioned between the light condensing unit and the photoelectric conversion unit, wherein
the additional polarizer includes a plurality of unit additional polarizers associated with each of the plurality of pixels, and
each of the plurality of unit additional polarizers selectively passes a polarized light corresponding to an associated pixel.

10. The photodetection device according to claim 9, wherein
the additional polarizer includes a wire grid polarizer.

11. The photodetection device according to claim 9, wherein
the additional polarizer includes a photonic crystal polarizer.

12. The photodetection device according to claim 1, further comprising:
a band-pass filter, wherein
the photoelectric conversion unit receives light that has passed through the band-pass filter.

13. The photodetection device according to claim 1, further comprising:
an on-chip lens including a plurality of microlenses, wherein
the incident light is incident on the polarization control unit after passing through the on-chip lens.

14. The photodetection device according to claim 13, wherein
each of the plurality of microlenses is associated with two or more pixels, and
the plurality of polarized lights in the incident light having passed through each of the plurality of microlenses is incident on two or more pixels associated with each other.

15. The photodetection device according to claim 1, wherein
the polarization control unit includes a plurality of unit polarization control units,
each of the plurality of unit polarization control units selectively emits a first polarized light oscillating in a first polarized light oscillation direction and a second polarized light oscillating in a second polarized light oscillation direction in the incident light,
a plurality of fine structures included in each of the plurality of unit polarization control units includes a first reference fine structure having a maximum length in the first polarized light oscillation direction, and a plurality of fine structures in which a length in the first polarized light oscillation direction gradually decreases as a distance from the first reference fine structure increases, and
a plurality of fine structures included in each of the plurality of unit polarization control units includes a second reference fine structure having a maximum length in the second polarized light oscillation direction, and a plurality of fine structures in which a length in the second polarized light oscillation direction gradually decreases as a distance from the second reference fine structure increases.

16. The photodetection device according to claim 15, wherein
each of the plurality of unit polarization control units is associated with two pixels among the plurality of pixels,
the first polarized light emitted from each of the plurality of unit polarization control units is condensed on one of the two pixels associated with each other via the light condensing unit, and
the second polarized light emitted from each of the plurality of unit polarization control units is condensed on another one of the two pixels associated with each other via the light condensing unit.

17. The photodetection device according to claim 1, wherein
the polarization control unit includes a plurality of unit polarization control units that selectively emits two polarized lights in the incident light,
each of the plurality of unit polarization control units covers a region corresponding to two pixels of the photoelectric conversion unit, and
the light condensing unit includes a plurality of unit light condensing units that condenses each of the two polarized lights on an adjacent pixel.

18. The photodetection device according to claim 17, wherein
the plurality of unit polarization control units includes:
a plurality of first unit polarization control units that selectively emits a first polarized light and a second polarized light in the incident light; and
a plurality of second unit polarization control units that selectively emits a third polarized light and a fourth polarized light in the incident light, and
the plurality of unit light condensing units includes:
a plurality of first unit light condensing units that condenses the first polarized light and the second polarized light on respectively adjacent pixels; and
a plurality of second unit light condensing units that condenses the third polarized light and the fourth polarized light on respectively adjacent pixels.

19. The photodetection device according to claim 18, wherein
the polarization control unit includes a plurality of sub-unit polarization control units, and
each of the plurality of sub-unit polarization controls includes the first unit polarization control unit and the second unit polarization control unit.
